(19) United States
(12) Patent Application Publication
(10) Pub. No.: US 2026/0114086 A1
(43) Pub. Date: Apr. 23, 2026

(54) LIGHT EMITTING ELEMENT, AND DISPLAY DEVICE AND ELECTRONIC DEVICE INCLUDING THE SAME

(71) Applicant: Samsung Display Co., LTD., Yongin-si (KR)

(72) Inventors: Jin Taek PARK, Yongin-si (KR); Jun Youn KIM, Yongin-si (KR); So Young YEO, Yongin-si (KR); Chul Jong YOO, Yongin-si (KR); Jae Hoon JUNG, Yongin-si (KR)

(21) Appl. No.: 19/212,765

(22) Filed: May 20, 2025

(30) Foreign Application Priority Data
Oct. 21, 2024 (KR) 10-2024-0144142

(51) Int. Cl. H10H 20/831; H10H 20/819; H10H 20/825

(52) U.S. Cl. CPC H10H 20/831; H10H 20/819; H10H 20/825

(57) ABSTRACT

A light emitting element according to an embodiment includes a semiconductor stack including a first semiconductor layer, an active layer, and a second semiconductor layer that are sequentially disposed in a thickness direction, wherein a thickness of the first semiconductor layer is 100 nm or less or is less than ⅙ of a thickness of the semiconductor stack.

### CROSS-REFERENCE

This application claims priority to Korean Patent Application No. 10-2024-0144142 filed on Oct. 21, 2024, and all the benefits accruing therefrom under 35 U.S.C. 119, the content of which in its entirety is herein incorporated by reference.

### BACKGROUND

### 1. Technical Field

The present disclosure relates to a light emitting element, and a display device and an electronic device including the same.

### 2. Description of the Related Art

Light emitting elements have been widely used as light sources of various electronic devices including display devices. As an example, the light emitting elements have been used as light sources of various electronic devices including virtual reality devices, augmented reality devices, or the like, as well as portable electronic devices including smartphones, smart watches, or the like, and televisions.

### SUMMARY

Aspects of the present disclosure provide a light emitting element having improved stability, and a display device and an electronic device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a light emitting element including a semiconductor stack including a first semiconductor layer, an active layer, and a second semiconductor layer that are sequentially disposed in a thickness direction. A thickness of the first semiconductor layer may be 100 nm or less or may be less than ⅙ of a thickness of the semiconductor stack.

In an embodiment, the first semiconductor layer may include an n-type semiconductor, and the second semiconductor layer may include a p-type semiconductor.

In an embodiment, a thickness of the semiconductor stack may be smaller than or equal to a width of the semiconductor stack.

In an embodiment, the light emitting element may further include an electrode layer disposed on a lower surface of the semiconductor stack, and the electrode layer may include a conductive material having a density higher than a density of a semiconductor material included in the semiconductor stack.

In an embodiment, the semiconductor stack may include gallium nitride (GaN), and the electrode layer may include at least one of hafnium (Hf), tantalum (Ta), molybdenum (Mo), tungsten (W), rhenium (Re), copper (Cu), silver (Ag), gold (Au), palladium (Pd), and platinum (Pt).

In an embodiment, a lower surface of the electrode layer may have a bend.

In an embodiment, the light emitting element may further include a reflective layer disposed between the lower surface of the semiconductor stack and the electrode layer.

In an embodiment, the light emitting element may further include an adhesive layer disposed on a lower surface of the semiconductor stack.

According to an aspect of the present disclosure, there is provided a light emitting element including a semiconductor stack including a first semiconductor layer, an active layer, and a second semiconductor layer that are sequentially disposed in a thickness direction, and an electrode layer disposed on a lower surface of the semiconductor stack. The electrode layer may include a conductive material having a density higher than a density of a semiconductor material included in the semiconductor stack.

In an embodiment, the semiconductor stack may include gallium nitride (GaN), and the electrode layer may include at least one of hafnium (Hf), tantalum (Ta), molybdenum (Mo), tungsten (W), rhenium (Re), copper (Cu), silver (Ag), gold (Au), palladium (Pd), and platinum (Pt).

In an embodiment, a lower surface of the electrode layer may have a bend.

In an embodiment, the light emitting element may further include a reflective layer disposed between the lower surface of the semiconductor stack and the electrode layer.

According to an aspect of the present disclosure, there is provided a display device including a backplane substrate, an electrode disposed on the backplane substrate, and a light emitting element disposed on the electrode. The light emitting element may include a semiconductor stack including a first semiconductor layer, an active layer, and a second semiconductor layer that are sequentially disposed in a thickness direction, and a thickness of the first semiconductor layer may be 100 nm or less or may be less than ⅙ of a thickness of the semiconductor stack.

In an embodiment, the first semiconductor layer may include an n-type semiconductor, and the second semiconductor layer may include a p-type semiconductor.

In an embodiment, a thickness of the semiconductor stack may be smaller than or equal to a width of the semiconductor stack.

In an embodiment, the light emitting element may further include an electrode layer disposed on a lower surface of the semiconductor stack, and the electrode layer may include a conductive material having a density higher than a density of a semiconductor material included in the semiconductor stack.

In an embodiment, the semiconductor stack may include gallium nitride (GaN), and the electrode layer may include at least one of hafnium (Hf), tantalum (Ta), molybdenum (Mo), tungsten (W), rhenium (Re), copper (Cu), silver (Ag), gold (Au), palladium (Pd), and platinum (Pt).

In an embodiment, a lower surface of the electrode layer may have a bend.

In an embodiment, the light emitting element may further include a reflective layer disposed between the lower surface of the semiconductor stack and the electrode layer.

In an embodiment, the light emitting element may further include an adhesive layer disposed on a lower surface of the semiconductor stack.

According to an aspect of the present disclosure, there is provided an electronic device including a display module including a display panel, and a processor configured to transmit an image data signal to the display module. The display panel may include a backplane substrate, an electrode disposed on the backplane substrate, and a light emitting element disposed on the electrode, the light emitting element may include a semiconductor stack including a first semiconductor layer, an active layer, and a second semiconductor layer that are sequentially disposed in a thickness direction, and a thickness of the first semiconductor layer may be 100 nm or less or may be less than ⅙ of a thickness of the semiconductor stack.

A light emitting element according to embodiments may have a low center of gravity and have improved stability. Accordingly, the light emitting element may be stably disposed on a mounting surface.

With the light emitting element according to embodiments, and a display device and an electronic device including the same, the light emitting element may be stably disposed on a backplane substrate of the display device or the electronic device, and the light emitting element and the backplane substrate may be stably connected to each other. Accordingly, a utilization rate of the light emitting element may be increased, and a yield of the display device or the electronic device may be improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a cross-sectional view illustrating a light emitting element according to an embodiment;

FIG. 2 is a cross-sectional view illustrating a light emitting element according to an embodiment;

FIGS. 3 and 4 are views illustrating a difference in stability between light emitting elements according to the centers of gravity of the light emitting elements;

FIG. 5 is a cross-sectional view illustrating a light emitting element according to an embodiment;

FIG. 6 is a cross-sectional view illustrating a light emitting element according to an embodiment;

FIG. 7 is a cross-sectional view illustrating a light emitting element according to an embodiment;

FIG. 8 is a cross-sectional view illustrating a light emitting element according to an embodiment;

FIG. 9 is a cross-sectional view illustrating a light emitting element according to an embodiment;

FIG. 10 is a view illustrating that stability of a light emitting element is improved as the center of gravity of the light emitting element is lowered;

FIG. 11 is a cross-sectional view illustrating a light emitting element according to an embodiment;

FIG. 12 is a cross-sectional view illustrating a light emitting element according to an embodiment;

FIG. 13 is a cross-sectional view illustrating a light emitting element according to an embodiment;

FIG. 14 is a cross-sectional view illustrating a light emitting element according to an embodiment;

FIG. 15 is a cross-sectional view illustrating a light emitting element according to an embodiment;

FIG. 16 is a cross-sectional view illustrating a light emitting element according to an embodiment;

FIG. 17 is a perspective view illustrating a display device according to an embodiment.

FIG. 18 is a cross-sectional view illustrating a display device according to an embodiment;

FIG. 19 is a cross-sectional view illustrating a display device according to an embodiment;

FIG. 20 is a view illustrating a smart watch including the display device according to an embodiment;

FIGS. 21 and 22 are views illustrating a head mounted display device including the display device according to an embodiment;

FIG. 23 is a view illustrating a head mounted display device including the display device according to an embodiment;

FIG. 24 is a view illustrating an instrument board and a center fascia of a vehicle including the display devices according to an embodiment; and

FIG. 25 is a view illustrating a transparent display device including the display device according to an embodiment.

FIG. 26 is a block diagram of an electronic device according to one embodiment of the present disclosure.

### DETAILED DESCRIPTION

One or more embodiments will now be described more fully hereinafter with reference to the accompanying drawings, in which various embodiments are shown. One or more embodiments may, however, be embodied in different forms and should not be construed as limited to the embodiments set forth herein. Rather, these embodiments are provided so that this disclosure will be thorough and complete, and will fully convey the scope of the claims to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings described herein. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

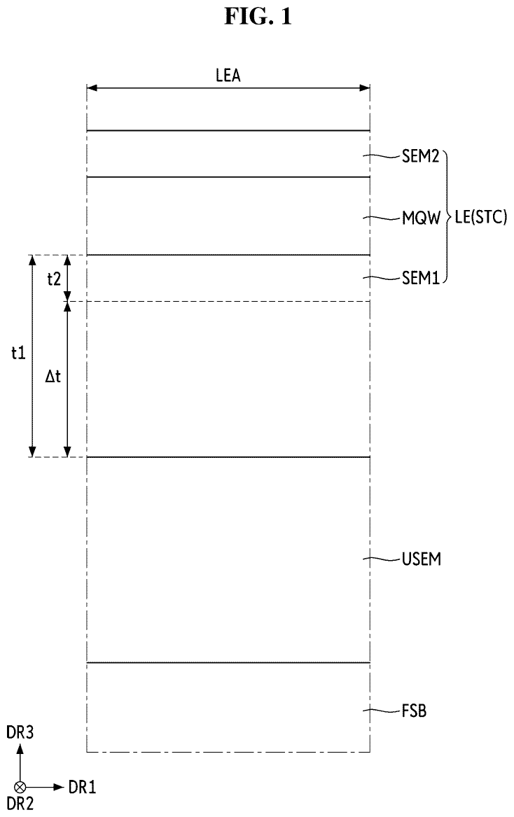

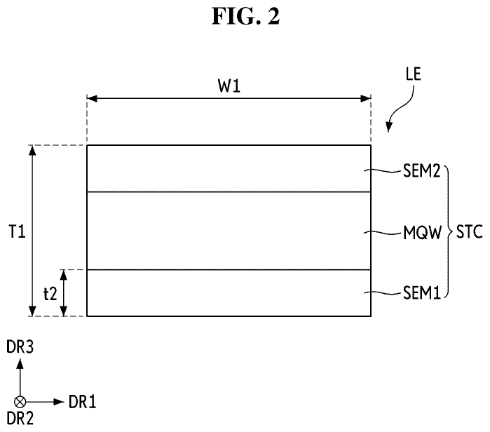

FIG. 1 is a cross-sectional view illustrating a light emitting element according to an embodiment. FIG. 2 is a cross-sectional view illustrating a light emitting element according to an embodiment. FIG. 1 illustrates a light emitting element LE that is formed on a substrate FSB and is not separated from the substrate FSB, and FIG. 2 illustrates a light emitting element LE that is etched or separated in an individual size and is separated from the substrate FSB.

Referring to FIGS. 1 and 2, the light emitting element LE may be manufactured on the substrate FSB and then separated from the substrate FSB. For example, semiconductor layers for forming a plurality of light emitting elements LE may be formed on the substrate FSB including a plurality of light emitting element areas LEA, and the light emitting elements LE may be separated into elements having individual sizes by performing a process such as etching or dicing. The light emitting element LE may be mounted on (e.g., bonded to) a mounting surface of an electronic device on which the light emitting element LE is to be mounted in a state in which it is separated from the substrate FSB or may be mounted on the mounting surface and then separated from the substrate FSB.

In FIG. 1, a first direction DR1, a second direction DR2, and a third direction DR3 that are perpendicular to each other are illustrated. As an example, the first direction DR1 and the second direction DR2 may be perpendicular to each other, and may define a plane parallel to a bottom surface of the light emitting element LE or the substrate FSB. The third direction DR3 may be a direction perpendicular to the first direction DR1 and the second direction DR2. As an example, the third direction DR3 is a direction perpendicular to a main surface of the substrate FSB, and may be a thickness direction of the substrate FSB or the light emitting element LE.

The substrate FSB may be a manufacturing substrate for manufacturing the light emitting element LE. For example, the substrate FSB may be a manufacturing substrate, a wafer, or the like, suitable for epitaxial growth for forming the semiconductor layers of the light emitting element LE. In an embodiment, the substrate FSB may be a semiconductor substrate including silicon (Si), sapphire, GaAs, SiC, GaN, ZnO, or other materials. A type or a material of the substrate FSB is not particularly limited as long as epitaxial growth for manufacturing the light emitting element LE may be smoothly performed.

In an embodiment, the substrate FSB may be used as a substrate for epitaxial growth for manufacturing the light emitting element LE, and then ultimately separated from the light emitting element LE. For example, after the semiconductor layers for forming the plurality of light emitting elements LE are formed (e.g., grown) on the substrate FSB, the semiconductor layers of the light emitting elements LE may be separated by an etching process, dicing, or the like, and the light emitting elements LE may be formed in the respective light emitting element areas LEA.

The light emitting element LE may have various shapes according to embodiments. In an embodiment, the light emitting element LE may include a side surface substantially perpendicular to the substrate FSB. As an example, the light emitting element LE may be manufactured in a columnar shape having a cross-sectional shape such as a rectangular shape or a square shape. However, a shape of the light emitting element LE is not limited thereto. For example, the light emitting element LE may also include a side surface inclined at a tapered angle with respect to the substrate FSB. As an example, the light emitting element LE may have a cross-sectional shape such as a trapezoidal shape or an inverted trapezoidal shape. In addition, the light emitting element LE may have various shapes in plan view according to embodiments. As an example, the light emitting element LE may have a rectangular shape, a square shape, a hexagonal shape, a circular shape, an elliptical shape, or other shapes when viewed on a plane defined by the first direction DR1 and the second direction DR2.

In an embodiment, the light emitting element LE may be an inorganic light emitting element made of an inorganic material. For example, the light emitting element LE may be an inorganic light emitting diode made of a nitride-based semiconductor material (e.g., GaN, AlGaN, GaAlN, InGaN, InAlGaN, AlN, InN, or other nitride-based semiconductor materials) or other inorganic materials. The light emitting element LE may emit light of a specific color. As an example, the light emitting element LE may emit red light, green light, blue light, or light of other colors. In an embodiment, an active layer MQW of the light emitting element LE may include indium, and may emit light of a color and/or a wavelength band corresponding to a composition of indium in the active layer MQW.

In an embodiment, the light emitting element LE may be a micro light emitting diode (micro LED) having a small size in a micrometer (μm) range. For example, the light emitting element LE may be a micro LED of which at least one of a length in the first direction DR1 (e.g., a width or a transverse length in the first direction DR1), a length in the second direction DR2 (e.g., a width or a longitudinal length in the second direction DR2), and a length in the third direction DR3 (e.g., a thickness or a height) is several micrometers (μm) to several hundreds of micrometers (μm). As an example, each of a length of the light emitting element LE in the first direction DR1, a length of the light emitting element LE in the second direction DR2, and a length of the light emitting element LE in the third direction DR3 may be 100 μm or less, but is not limited thereto.

The light emitting element LE may include a semiconductor stack STC including a plurality of semiconductor layers disposed or stacked on the substrate FSB. For example, the semiconductor stack STC of the light emitting element LE may include a first semiconductor layer SEM1, the active layer MQW, and a second semiconductor layer SEM2 that are sequentially formed (e.g., sequentially grown) on the substrate FSB in the thickness direction of the light emitting element LE.

In an embodiment, in order to smoothly grow the semiconductor stack STC of the light emitting element LE, an undoped semiconductor layer USEM (or a buffer layer) may be first formed on the substrate FSB, and the first semiconductor layer SEM1, the active layer multiple quantum well (MQW), and the second semiconductor layer SEM2 may then be sequentially grown on the undoped semiconductor layer USEM. The undoped semiconductor layer USEM may provide a stable base for forming the semiconductor layers of the light emitting element LE.

In an embodiment, the undoped semiconductor layer USEM may include a nitride-based semiconductor material. As an example, the undoped semiconductor layer USEM may include gallium nitride (hereinafter referred to as GaN), and may be substantially undoped. The undoped semiconductor layer USEM may be formed at a thickness (e.g., a thickness of 1 μm or more) appropriate for smoothly growing the semiconductor layers of the light emitting element LE thereon. As long as the semiconductor layers of the light emitting element LE may be smoothly grown on the undoped semiconductor layer USEM, a material or a thickness of the undoped semiconductor layer USEM is not particularly limited. In an embodiment, the undoped semiconductor layer USEM may ultimately be separated or removed from the light emitting element LE. For example, the light emitting element LE that is individually separated or manufactured as illustrated in FIG. 2 may not include the undoped semiconductor layer USEM.

The first semiconductor layer SEM1 may be disposed on the undoped semiconductor layer USEM. The first semiconductor layer SEM1 may be a semiconductor layer doped with a first conductivity-type dopant. For example, the first semiconductor layer SEM1 may include a semiconductor material including a first conductivity-type dopant.

In an embodiment, the first semiconductor layer SEM1 may include a nitride-based semiconductor material (e.g., GaN) and a first conductivity-type dopant doped into the nitride-based semiconductor material. As an example, the first semiconductor layer SEM1 may include an n-type semiconductor (e.g., n-GaN) doped with an n-type dopant such as Si, Ge, or Sn, but is not limited thereto.

The active layer MQW may be disposed on the first semiconductor layer SEM1. The active layer MQW may emit light by recombination of electron-hole pairs generated according to electrical signals applied through the first semiconductor layer SEM1, the second semiconductor layer SEM2, and the like.

The active layer MQW may include a nitride-based semiconductor material or other semiconductor materials, and may have a single or multiple quantum well structure. For example, the active layer MQW may include at least one quantum well layer including a nitride-based semiconductor material (e.g., InGaN or AlInGaN) including indium. In an embodiment, the active layer MQW may have a multiple quantum well structure including a plurality of quantum well layers including InGaN and a plurality of barrier layers including GaN, AlGaN, or GaAlN. However, a material or a structure of the active layer MQW may be changed according to embodiments.

In an embodiment, the active layer MQW may emit light of a visible ray wavelength band such as light of a wavelength band of approximately 400 nm to 900 nm. For example, the active layer MQW may emit blue light having a peak wavelength of a range of approximately 440 nm to 480 nm, green light having a peak wavelength of a range of approximately 510 nm to 550 nm, or red light having a peak wavelength of a range of approximately 610 nm to 750 nm. The active layer MQW may also emit light of a color or a wavelength band other than the colors or the wavelength bands exemplified above.

In an embodiment, a color of the light emitted from the active layer MQW may be controlled or changed by adjusting the composition of indium included in the active layer MQW. As an example, an emission wavelength of the active layer MQW may be controlled so that the active layer MQW emits the blue light by controlling the composition of indium included in the active layer MQW to 10% to 20%. Alternatively, an emission wavelength of the active layer MQW may be controlled so that the active layer MQW emits the green light by controlling the composition of indium included in the active layer MQW to 20% to 30%, and an emission wavelength of the active layer MQW may be controlled so that the active layer MQW emits the red light by controlling the composition of indium included in the active layer MQW to 30% to 40%.

The second semiconductor layer SEM2 may be disposed on the active layer MQW. The first second semiconductor layer SEM2 may be a semiconductor layer doped with a second conductivity-type dopant. For example, the second semiconductor layer SEM2 may include a semiconductor material including a second conductivity-type dopant.

In an embodiment, the second semiconductor layer SEM2 may include a nitride-based semiconductor material (e.g., GaN) and a second conductivity-type dopant doped into the nitride-based semiconductor material. As an example, the second semiconductor layer SEM2 may include a p-type semiconductor (e.g., p-GaN) doped with a p-type dopant such as Mg, Zn, Ca, Se, or Ba, but is not limited thereto.

In an embodiment, the light emitting element LE may include the first semiconductor layer SEM1 having a limited thickness. For example, the first semiconductor layer SEM1 may be formed at a thickness t1 (see FIG. 1) appropriate for securing a growth quality and mechanical stability of the semiconductor stack STC and then etched or removed by a partial thickness Δt (see FIG. 1) to have a reduced thickness t2 (see FIGS. 1 and 2). As an example, the first semiconductor layer SEM1 may be formed at a thickness of 1 μm or more and then etched by 90% or more of the thickness to have a final thickness of 100 nm or less.

The first semiconductor layer SEM1 is grown to the thickness of 1 μm or more, and accordingly, the semiconductor stack STC of the light emitting element LE may be smoothly grown. Accordingly, a high-quality light emitting element LE may be manufactured.

By etching the first semiconductor layer SEM1 to reduce the final thickness of the first semiconductor layer SEM1, an entire thickness (a first thickness T1 (see FIG. 2) of the semiconductor stack STC or the light emitting element LE may be reduced or minimized. For example, when the first semiconductor layer SEM1 is formed at a thickness of 100 nm or less, a thickness of the semiconductor stack STC and the light emitting element LE including the semiconductor stack STC may be significantly reduced. Accordingly, stability (e.g., a base surface seating property) of the light emitting element LE may be effectively improved without loss of an area or a volume of the active layer MQW. For example, by reducing or minimizing the thickness of the first semiconductor layer SEM1 to 100 nm or less, the center of gravity (CG) of the light emitting element LE may be lowered compared to a size (e.g., a volume) of the light emitting element LE. Accordingly, when the light emitting element LE is mounted on the mounting surface of the electronic device, stability of dropping or transfer of the light emitting element LE may be improved, and the light emitting element LE may be stably disposed on the mounting surface. On the other hand, in the case of the light emitting element LE in which a thickness of the first semiconductor layer SEM1 is greater than 100 nm, the center of gravity of the light emitting element LE may be relatively high. As an example, in the light emitting element LE in which the final thickness of the first semiconductor layer SEM1 is greater than 100 nm even though the thickness of the first semiconductor layer SEM1 is partially reduced, an amount of change in the center of gravity of the light emitting element LE is relatively small, such that the center of gravity of the light emitting element LE may be relatively high. Accordingly, in the light emitting element LE in which the final thickness of the first semiconductor layer SEM1 is greater than 100 nm, a stability improvement effect of the light emitting element LE may be reduced.

In an embodiment, the thickness t2 (see FIG. 2) of the first semiconductor layer SEM1 may be 20% or less of the thickness (the first thickness T1 (see FIG. 2)) of the semiconductor stack STC or the light emitting element LE. For example, the first semiconductor layer SEM1 may have a thickness limited to a thickness less than ⅙ of the thickness of the semiconductor stack STC (or the light emitting element LE). As an example, the thickness of the first semiconductor layer SEM1 may be reduced or minimized to have a value smaller than or equal to a thickness of the active layer MQW. Accordingly, a ratio of the thickness of the first semiconductor layer SEM1 to the entire thickness (the first thickness T1 of FIG. 2) of the semiconductor stack STC may be reduced or minimized. The entire thickness of the semiconductor stack STC and the light emitting element LE including the semiconductor stack STC may be reduced through the reduction in the thickness of the first semiconductor layer SEM1 to improve the stability (e.g., the base surface seating property) of the light emitting element LE. In the case of the light emitting element LE in which the thickness of the first semiconductor layer SEM1 is ⅙ or more of the thickness of the semiconductor stack STC (or the thickness of the light emitting element LE), the center of gravity of the light emitting element LE may be relatively high. As an example, in the light emitting element LE in which the thickness of the first semiconductor layer SEM1 is ⅙ or more of the thickness of the semiconductor stack STC even though the thickness of the first semiconductor layer SEM1 is partially reduced, an amount of change in the center of gravity of the light emitting element LE is relatively small, such that the center of gravity of the light emitting element LE may be relatively high. Accordingly, in the light emitting element LE in which the thickness of the first semiconductor layer SEM1 is ⅙ or more of the thickness of the semiconductor stack STC, a stability improvement effect of the light emitting element LE may be reduced.

In an embodiment, the first semiconductor layer SEM1 may be grown as a bulk layer having a thickness greater than or equal to a thickness of each of the second semiconductor layer SEM2 and the active layer MQW and then etched to have a reduced thickness t2 (see FIGS. 1 and 2). Accordingly, a difference between the thickness of the first semiconductor layer SEM1 and the thickness of the second semiconductor layer SEM2 and/or a difference between the thickness of the first semiconductor layer SEM1 and the thickness of the active layer MQW may be reduced. As an example, the thickness of the first semiconductor layer SEM1 of the light emitting element LE separated from the substrate FSU and the undoped semiconductor layer USEM may be similar to the thickness of the second semiconductor layer SEM2 or the active layer MQW or may be smaller than or equal to the thickness of the second semiconductor layer SEM2 or the active layer MQW. A final thickness t2 (see FIG. 2) of the first semiconductor layer SEM1 may be appropriately changed or adjusted according to embodiments in consideration of at least one of a size, a shape, characteristics (e.g., a carrier concentration), and performance (e.g., luminous efficiency) of the light emitting element LE.

In an embodiment, the light emitting element LE may have a shape or an aspect ratio suitable or optimized for having a low center of gravity. For example, an aspect ratio of the light emitting element LE may be 1 or less.

In an embodiment, the aspect ratio of the light emitting element LE based on the semiconductor stack STC may be 1 or less. For example, the semiconductor stack STC of the light emitting element LE may have a first width W1 in the first direction DR1 and the first thickness T1 in the third direction DR3, and the first width W1 may be greater than or equal to the first thickness T1. In an embodiment, a length of the semiconductor stack STC in the second direction DR2 (e.g., a width of the semiconductor stack STC in the second direction DR2) may also be greater than or equal to the first thickness T1.

As in an embodiment, the semiconductor stack STC whose thickness is smaller than or equal to the width and the light emitting element LE including the semiconductor stack STC may have a low center of gravity. Accordingly, when the light emitting element LE is transferred onto the mounting surface using a method such as dropping or transfer, the light emitting element LE may be more stably seated on or fixed onto the mounting surface.

In an embodiment, each of the length of the light emitting element LE in the first direction DR1, the length of the light emitting element LE in the second direction DR2, and the length of the light emitting element LE in the third direction DR3 may be 5 μm or less. Accordingly, the light emitting element LE may be usefully used in an ultrahigh-resolution electronic device.

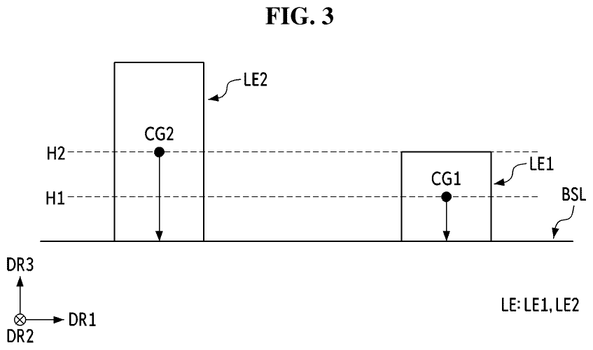

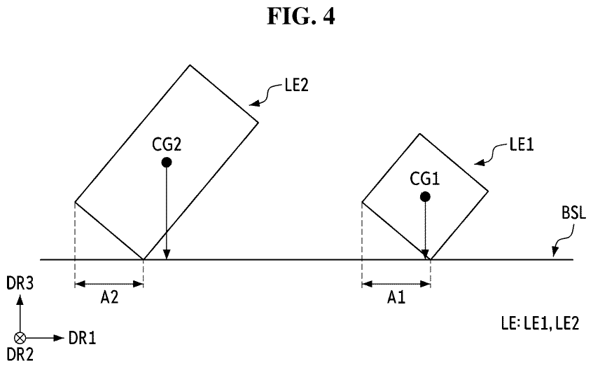

FIGS. 3 and 4 are views illustrating a difference in stability between light emitting elements according to the centers of gravity of the light emitting elements. For example, FIG. 3 illustrates a difference in stability (e.g., a base surface seating property) between light emitting elements LE according to the centers of gravity CG1 and CG2 of the light emitting elements LE when the light emitting elements LE are dropped or transferred in a vertical direction, and FIG. 4 illustrates a difference in stability between light emitting elements LE according to the centers of gravity CG1 and CG2 of the light emitting elements LE when the light emitting elements LE are dropped or transferred in a state in which they are inclined in a diagonal direction.

Referring to FIGS. 3 and 4, the light emitting element LE may be disposed on a base surface BSL (or a transfer surface) by dropping, transferring, or other methods. The base surface BSL is a surface on which the light emitting element LE is mounted or transferred, and may be, for example, the mounting surface of the electronic device on which the light emitting element LE is mounted. For example, when the light emitting element LE is mounted on a backplane substrate of a display device, the base surface BSL may be an upper surface of the backplane substrate (or an upper surface of a pixel electrode disposed on the upper surface of the backplane substrate).

As described in an embodiment of FIGS. 1 and 2, when the thickness of the first semiconductor layer SEM1 is reduced to lower the aspect ratio of the light emitting element LE, the center of gravity of the light emitting element LE may be lowered. For example, as illustrated in FIG. 3, a first light emitting element LE1 vertically dropped or transferred onto the base surface BSL and having an aspect ratio of 1 or less may have a first center of gravity CG1 positioned at a first height H1 from the base surface BSL (or a lower surface of the first light emitting element LE1), and a second light emitting element LE2 vertically dropped or transferred onto the base surface BSL and having an aspect ratio greater than 1 (having a thickness greater than a width) may have a second center of gravity CG2 positioned at a second height H2 from the base surface BSL (or a lower surface of the second light emitting element LE2). The first height H1 may be smaller than the second height H2. Accordingly, a base surface mounting property of the first light emitting element LE1 may be higher than a base surface mounting property of the second light emitting element LE2. For example, the possibility of vertical drop (or vertical transfer) of the first light emitting element LE1 or the stability immediately after the drop (or the transfer) of the first light emitting element LE1 may be higher than the possibility of vertical drop of the second light emitting element LE2 or the stability immediately after the drop of the second light emitting element LE2.

In addition, as illustrated in FIG. 4, when the light emitting element LE is diagonally dropped or transferred on the base surface BSL, depending on an angle at which the light emitting element LE is inclined, a shape of the light emitting element LE, or the like, the center of gravity of the light emitting element LE may be positioned within an area overlapping a lower surface of the light emitting element LE in a direction perpendicular to the base surface BSL (e.g., the third direction DR3) (e.g., a body area overlapping the lower surface of the light emitting element LE in the third direction DR3) or may be out of the area overlapping the lower surface of the light emitting element LE. For example, even though the first light emitting element LE1 and the second light emitting element LE2 are dropped in a state in which they are inclined at the same angle, the possibility that the center of gravity CG1 of the first light emitting element LE1 will be positioned within a first area A1 overlapping the lower surface of the first light emitting element LE1 in the third direction DR3 may be high, whereas the possibility that the center of gravity CG2 of the second light emitting element LE2 will be positioned within a second area A2 overlapping the lower surface of the second light emitting element LE2 may be low. For example, the possibility that the center of gravity CG2 of the second light emitting element LE2 will be out of the second area A2 may be higher than the possibility that the center of gravity CG1 of the first light emitting element LE1 will be out of the first area A1. Accordingly, stability or an alignment degree of the drop (or the transfer) of the second light emitting element LE2 may be lower than stability or an alignment degree of the drop (or the transfer) of the first light emitting element LE1.

As in an embodiment of FIGS. 1 and 2, in the case of the light emitting element LE including the first semiconductor layer SEM1 having the reduced thickness t2 (see FIGS. 1 and 2), the aspect ratio may be lowered. As an example, the semiconductor stack STC of the light emitting element LE may have the first thickness T1 and the first width W1 greater than or equal to the first thickness T1, and an aspect ratio of the semiconductor stack STC may be 1 or less. Accordingly, when the light emitting element LE is dropped or transferred, the stability or the alignment degree of the light emitting element LE may be improved.

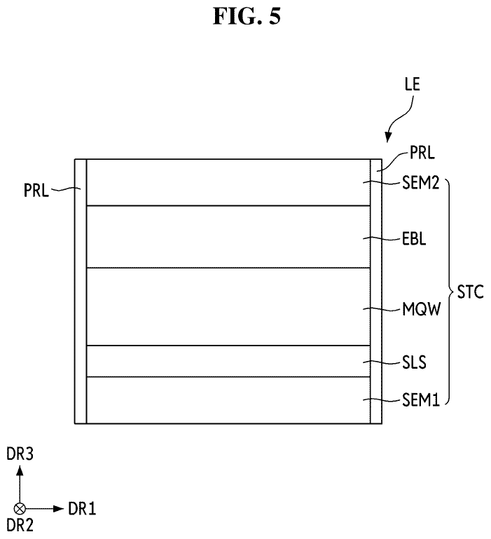

FIG. 5 is a cross-sectional view illustrating a light emitting element according to an embodiment. FIG. 5 illustrates a light emitting element LE including an additional component compared to FIG. 2. In describing the following embodiments, components that are substantially the same as or similar to those of at least one embodiment described above will be denoted by the same reference numerals, and an overlapping description thereof will be omitted. Each embodiment disclosed herein may be applied alone or be combined with at least one other embodiment.

Referring to FIG. 5, the light emitting element LE may further include at least one of a superlattice layer SLS (or a stress relaxation layer), an electron blocking layer EBL, and a protective layer PRL. The superlattice layer SLS and the electron blocking layer EBL may be included in the semiconductor stack STC. The protective layer PRL may be disposed on a side surface of the semiconductor stack STC.

The superlattice layer SLS may be disposed between the first semiconductor layer SEM1 and the active layer MQW. The superlattice layer SLS may adjust a lattice between the first semiconductor layer SEM1 and the active layer MQW, and control the movement of electrons. In an embodiment, the superlattice layer SLS may include a nitride-based semiconductor material (e.g., InGaN or AlInGaN) including indium, and a composition of indium in the superlattice layer SLS may be lower than a composition of indium in the active layer MQW.

The electron blocking layer EBL may be disposed between the active layer MQW and the second semiconductor layer SEM2. The electron blocking layer EBL may increase the possibility that electrons and holes will be recombined with each other within the active layer MQW by preventing electrons injected from the active layer MQW from moving to the second semiconductor layer SEM2. In an embodiment, the electron blocking layer EBL may include GaN doped with aluminum, such as AlGaN, but is not limited thereto.

In an embodiment, even though the semiconductor stack STC further includes the additional component, the first semiconductor layer SEM1 may have a limited thickness. For example, a thickness of the first semiconductor layer SEM1 may be 100 nm or less or be less than ⅙ of the thickness of the semiconductor stack STC. Alternatively, a thickness of the first semiconductor layer SEM1 may be 100 nm or less and be less than ⅙ of the thickness of the semiconductor stack STC.

In an embodiment, even though the semiconductor stack STC further includes the additional component, an aspect ratio of the semiconductor stack STC may be 1 or less. For example, the thickness of the semiconductor stack STC (e.g., a length of the semiconductor stack STC in the third direction DR3) may be smaller than or equal to a width of the semiconductor stack STC (e.g., a length of the semiconductor stack STC in the first direction DR1 or the second direction DR2). Accordingly, stability of the light emitting element LE may be secured or improved.

The protective layer PRL may surround the side surface of the semiconductor stack STC. For example, the protective layer PRL may surround an outer surface of the semiconductor stack STC when viewed on the plane defined by the first direction DR1 and the second direction DR2. The protective layer PRL may expose an upper surface and a lower surface of the semiconductor stack STC. In an embodiment, the protective layer PRL may include an insulating material capable of appropriately protecting the semiconductor layers of the semiconductor stack STC and preventing a short-circuit defect, and may have a single-layer or multi-layer structure. As an example, the protective layer PRL may include at least one inorganic insulating layer including an inorganic insulating material (e.g., silicon oxide (SiOₓ), silicon nitride (SiNₓ), silicon oxynitride (SiOₓN_{y}), silicon oxycarbide (SiOₓC_{y}), aluminum oxide (AlₓO_{y}), aluminum nitride (AlNₓ), zirconium oxide (ZrOₓ), hafnium oxide (HfOₓ), titanium oxide (TiOₓ), or other inorganic insulating materials). The protective layer PRL may also be omitted.

In an embodiment, the light emitting element LE may further include an additional component in addition to the superlattice layer SLS, the electron blocking layer EBL, and the protective layer PRL. For example, the light emitting element LE may further include at least one functional layer included in the semiconductor stack STC and/or at least one conductive layer disposed on at least one of the upper surface and the lower surface of the semiconductor stack STC. In addition, a structure of the light emitting element LE may be variously changed according to embodiments.

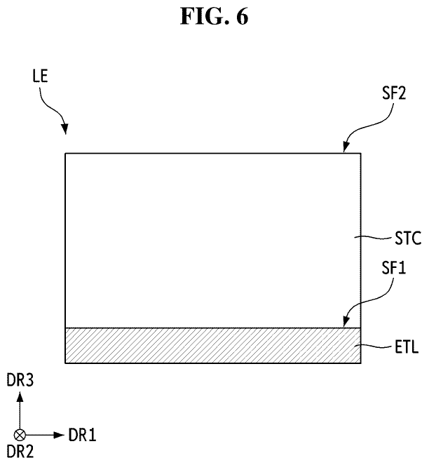

FIG. 6 is a cross-sectional view illustrating a light emitting element according to an embodiment. FIG. 6 illustrates a light emitting element LE including an additional component compared to FIG. 2.

Referring to FIG. 6, the light emitting element LE may further include an electrode layer ETL disposed on one surface of the semiconductor stack STC.

The semiconductor stack STC may include a first surface SF1 and a second surface SF2. For example, the first surface SF1 and the second surface SF2 may be a lower surface and an upper surface of the semiconductor stack STC, respectively. The first surface SF1 of the semiconductor stack STC may correspond to the lower surface of the semiconductor stack STC based on a direction in which the light emitting element LE is mounted on the electronic device.

One of the first semiconductor layer SEM1 and the second semiconductor layer SEM2 (or a conductive layer covering one surface of the one semiconductor layer) may be disposed on the first surface SF1 of the semiconductor stack STC. The other of the first semiconductor layer SEM1 and the second semiconductor layer SEM2 (or a conductive layer covering one surface of the other semiconductor layer) may be disposed on the second surface SF2 of the semiconductor stack STC. Depending on a disposition direction (e.g., a mounting direction) of the light emitting element LE, types of the semiconductor layers disposed on the first surface SF1 and the second surface SF2 of the semiconductor stack STC may change.

The electrode layer ETL may be disposed on the lower surface of the semiconductor stack STC. For example, the electrode layer ETL may be disposed below the first surface SF1 of the semiconductor stack STC, and may be disposed at the lowermost portion of the light emitting element LE. When the light emitting element LE is mounted on the mounting surface of the electronic device, the light emitting element LE may be disposed so that the electrode layer ETL faces downward. For example, the electrode layer ETL may be disposed at the lowermost portion of the light emitting element LE. In this case, a lower surface of the electrode layer ETL may form a bottom surface of the light emitting element LE.

The electrode layer ETL may include a conductive material (e.g., a metal having a density higher than a density (6.15 g/cm³) of GaN) having a higher density than a main semiconductor material (e.g., GaN) included in the semiconductor stack STC. For example, when the semiconductor stack STC includes GaN, the electrode layer ETL may include a conductive material having a relative density (Density/GaN) higher than 1 with respect to GaN, such as hafnium (Hf), niobium (Nb), tantalum (Ta), chromium (Cr), molybdenum (Mo), tungsten (W), rhenium (Re), copper (Cu), silver (Ag), gold (Au), palladium (Pd), or platinum (Pt), or alloys thereof, among conductive materials exemplified in Table 1.

TABLE 1

| | Density[g/cm³] | Density/GaN |
|---|---|---|
| Al | 2.71 | 0.44 |
| Ga | 5.91 | 0.96 |
| Hf | 13.31 | 2.16 |
| V | 6.11 | 0.99 |
| Nb | 8.57 | 1.39 |
| Ta | 16.69 | 2.71 |
| Cr | 7.15 | 1.16 |
| Mo | 10.28 | 1.67 |
| W | 19.25 | 3.13 |
| Re | 21.02 | 3.42 |
| Cu | 8.96 | 1.46 |
| Ag | 10.49 | 1.71 |
| Au | 19.3 | 3.14 |
| Pd | 12.02 | 1.95 |
| Pt | 21.45 | 3.49 |

The electrode layer ETL may function as a weight to lower the center of gravity of the light emitting element LE. For example, the electrode layer ETL having a higher density than the semiconductor stack STC is disposed below the semiconductor stack STC, and accordingly, the center of gravity of the light emitting element LE may be positioned closer to a lower surface of the light emitting element LE than an upper surface of the light emitting element LE. Accordingly, by lowering the center of gravity, stability of the light emitting element LE may be improved. In an embodiment, the electrode layer ETL may be made of a material that may be stably bonded or connected to an electrode or the like on the mounting surface among materials having a relative density (Density/GaN) higher than 1 with respect to GaN. As an example, the electrode layer ETL may include at least one of hafnium (Hf), tantalum (Ta), molybdenum (Mo), tungsten (W), rhenium (Re), copper (Cu), silver (Ag), gold (Au), palladium (Pd), and platinum (Pt). Accordingly, a bonding quality of the light emitting element LE may be improved.

In an embodiment, when the semiconductor layers of the semiconductor stack STC include GaN, the electrode layer ETL may include a conductive material having a relative density of 1.4 or more with respect to GaN, such as hafnium (Hf), tantalum (Ta), molybdenum (Mo), tungsten (W), rhenium (Re), copper (Cu), silver (Ag), gold (Au), palladium (Pd), or platinum (Pt), or alloys thereof. Accordingly, the center of gravity of the light emitting element LE may be more significantly lowered, and the stability of the light emitting element LE may be more effectively improved. In an embodiment, when the electrode layer ETL is formed using a conductive material having a relative density of 3 or more with respect to GaN, such as tungsten (W), rhenium (Re), gold (Au), or platinum (Pt), the center of gravity of the light emitting element LE may be more effectively adjusted.

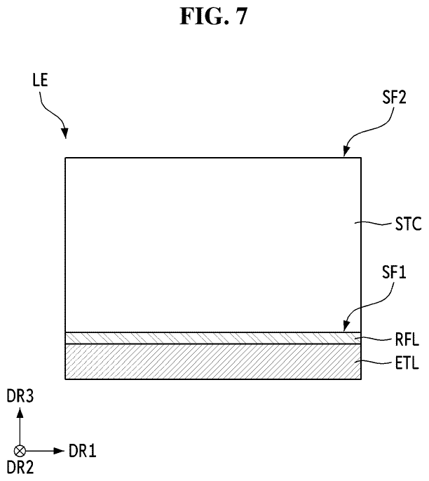

FIG. 7 is a cross-sectional view illustrating a light emitting element according to an embodiment. FIG. 7 illustrates a light emitting element LE including an additional component compared to FIG. 6.

Referring to FIG. 7, the light emitting element LE may further include a reflective layer RFL disposed between the semiconductor stack STC and the electrode layer ETL. As an example, the reflective layer RFL may be disposed between the first surface SF1 corresponding to the lower surface of the semiconductor stack STC and the electrode layer ETL based on the disposition direction (e.g., the mounting direction) of the light emitting element LE.

The reflective layer RFL may include a conductive material (e.g., a metal) having a relatively high reflectivity. As an example, the reflective layer RFL may include aluminum (Al) or include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), chromium (Cr), etc.) having a high light reflectivity.

By disposing the reflective layer RFL on the lower surface of the semiconductor stack STC, light efficiency (e.g., a light emission rate) of the light emitting element LE may be improved. For example, light generated in the active layer MQW of the semiconductor stack STC and directed to a lower portion of the semiconductor stack STC may be reflected by the reflective layer RFL. Accordingly, an amount of light transmitted through the second surface SF2 of the semiconductor stack STC and emitted above the light emitting element LE may be increased, and the light efficiency of the light emitting element LE may be improved.

In an embodiment, the reflective layer RFL may include a conductive material (e.g., a metal having a density higher than a density of GaN) having a higher density than a main semiconductor material (e.g., GaN) forming the semiconductor stack STC. As an example, when the semiconductor layers of the semiconductor stack STC include GaN, the reflective layer RFL may include hafnium (Hf), niobium (Nb), tantalum (Ta), chromium (Cr), molybdenum (Mo), tungsten (W), rhenium (Re), copper (Cu), silver (Ag), gold (Au), palladium (Pd), or platinum (Pt) having a relative density higher than 1 (Density/GaN) with respect to GaN, or alloys thereof, among the conductive materials exemplified in Table 1. Accordingly, the center of gravity of the light emitting element LE may be lowered, and the stability of the light emitting element LE may be improved.

An embodiment in which the light emitting element LE includes both the reflective layer RFL and the electrode layer ETL has been illustrated in FIG. 7, but embodiments are not limited thereto. For example, in other embodiments, the reflective layer RFL and the electrode layer ETL may also be integrated with each other. As an example, when the electrode layer ETL of FIG. 6 includes a conductive material having a higher density than the main material (e.g., GaN) forming the semiconductor stack STC and reflectivity of the electrode layer ETL is a reference value or more, the electrode layer ETL may function as a reflective layer while functioning as a weight lowering the center of gravity of the light emitting element LE.

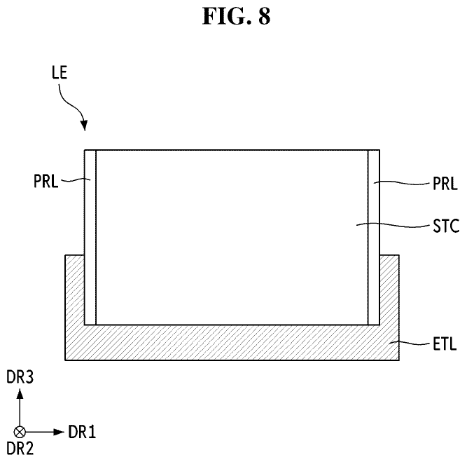

FIG. 8 is a cross-sectional view illustrating a light emitting element according to an embodiment. FIG. 8 illustrates a light emitting element LE in which a shape of the electrode layer ETL is different from that of FIG. 6.

Referring to FIG. 8, the electrode layer ETL may surround a portion of the side surface of the semiconductor stack STC. For example, the electrode layer ETL may extend to a height smaller than a height of the semiconductor stack STC and a width wider than a width of the semiconductor stack STC so as to surround a lower portion of the semiconductor stack STC. A shape or an extension length of the electrode layer ETL may be variously changed according to embodiments.

In an embodiment, the light emitting element LE includes a protective layer PRL surrounding the side surface of the semiconductor stack STC, and the electrode layer ETL may be disposed on the protective layer PRL. Accordingly, electrical stability between the semiconductor stack STC and the electrode layer ETL may be secured.

In an embodiment, even though the light emitting element LE further includes an additional component as in embodiments of FIGS. 6 to 8, the first semiconductor layer SEM1 may have a limited thickness. For example, a thickness of the first semiconductor layer SEM1 may be 100 nm or less or be less than ⅙ of the thickness of the semiconductor stack STC. Alternatively, a thickness of the first semiconductor layer SEM1 may be 100 nm or less and be less than ⅙ of the thickness of the semiconductor stack STC. However, embodiments are not limited thereto. As an example, when the light emitting element LE further includes an element (e.g., at least one of the electrode layer ETL and the reflective layer RFL) serving as a weight, the first semiconductor layer SEM1 may also have a thickness equal to or greater than the thickness exemplified above.

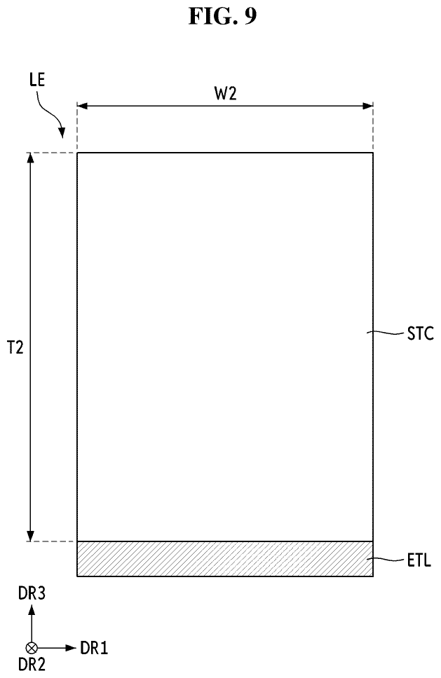

FIG. 9 is a cross-sectional view illustrating a light emitting element according to an embodiment. FIG. 9 illustrates a light emitting element LE in which a shape or a size of the semiconductor stack STC is different from that of FIG. 6.

Referring to FIG. 9, the semiconductor stack STC may have an expanded length in the third direction DR3. For example, the semiconductor stack STC may have a second width W2 in the first direction DR1 and a second thickness T2 in the third direction DR3, and the second thickness T2 may be greater than the second width W2. Accordingly, an aspect ratio (e.g., T2:W2) of the semiconductor stack STC may be greater than 1.

In an embodiment, the first semiconductor layer SEM1 included in the semiconductor stack STC may have a thickness greater than 100 nm. For example, the first semiconductor layer SEM1 may have a thickness (e.g., t1 (see FIG. 1)) grown on the substrate FSB or may be etched so that the remaining thickness is greater than 100 nm even though it is etched by a partial thickness. Accordingly, performance of the first semiconductor layer SEM1 may be improved.

The light emitting element LE may include an electrode layer ETL disposed on the lower surface of the semiconductor stack STC. The electrode layer ETL may include a conductive material having a density higher than a density of the semiconductor material (e.g., GaN) included in the semiconductor stack STC. For example, the electrode layer ETL may include at least one of the metals exemplified above with reference to Table 1. Accordingly, even though the thickness (e.g., the second thickness T2) of the semiconductor stack STC increases, the center of gravity of the light emitting element LE may be lowered by the electrode layer ETL. As an example, the center of gravity of the light emitting element LE may be positioned at a height smaller than ½ of the total height of the light emitting element LE.

As in the embodiments described above, the light emitting element LE may further include a reflective layer RFL disposed between the semiconductor stack STC and the electrode layer ETL or may not include the reflective layer RFL. Alternatively, by forming the electrode layer ETL using a material having a high reflectivity, the electrode layer ETL may also function as a reflective layer.

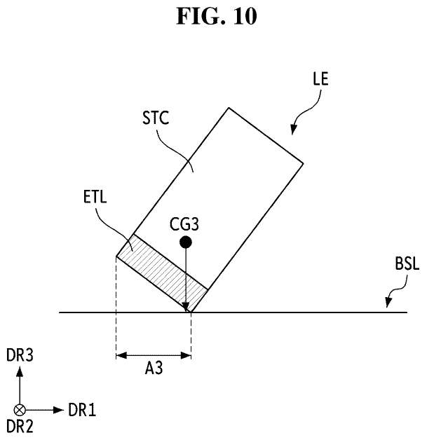

FIG. 10 is a view illustrating that stability of a light emitting element is improved as the center of gravity of the light emitting element is lowered. For example, FIG. 10 illustrates that stability of a light emitting element LE is improved as the center of gravity CG3 of the light emitting element LE is lowered by the electrode layer ETL when the light emitting element LE in which an aspect ratio of a semiconductor stack STC is greater than 1 is dropped or transferred in a state in which the light emitting element LS is inclined in the diagonal direction.

Referring to FIGS. 9 and 10, the center of gravity CG3 of the light emitting element LE is lowered by the electrode layer ETL, and accordingly, stability of the light emitting element LE may be further improved. For example, as the center of gravity CG3 of the light emitting element LE is lowered, possibility of vertical drop (or vertical transfer) of the light emitting element LE or stability immediately after drop (or transfer) of the light emitting element LE may be improved. In addition, as the center of gravity CG3 of the light emitting element LE is lowered, even though the light emitting element LE is diagonally dropped or transferred on the base surface BSL, the possibility that the center of gravity CG3 of the light emitting element LE will be positioned within a third area A3 overlapping the lower surface of the light emitting element LE in the direction perpendicular to the base surface BSL (e.g., the third direction DR3) may be increased. As an example, even in the case of the light emitting element LE in which a thickness of the semiconductor stack STC is greater than a width of the semiconductor stack STC, the center of gravity CG3 of the light emitting element LE is lowered by the electrode layer ETL, and accordingly, the stability of the light emitting element LE may be improved. In addition, even in the case of the light emitting element LE in which a thickness of the semiconductor stack STC is smaller than or equal to a width of the semiconductor stack STC, the center of gravity CG3 of the light emitting element LE is lowered by the electrode layer ETL, and accordingly, the stability of the light emitting element LE may be further improved. Accordingly, stability or an alignment degree (e.g., a base surface seating property) of the light emitting element LE during dropping or transfer of the light emitting element LE may be improved.

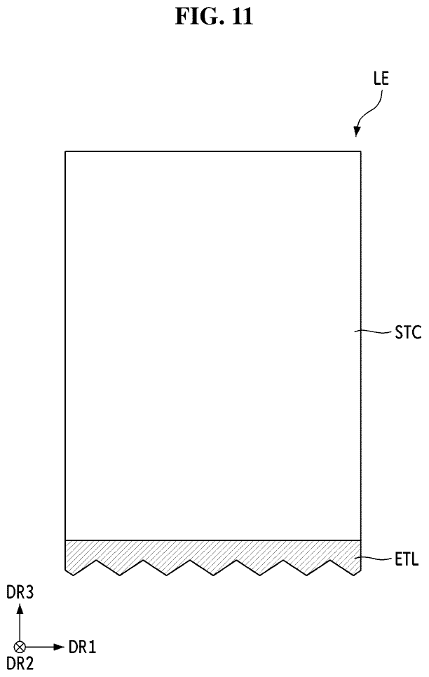

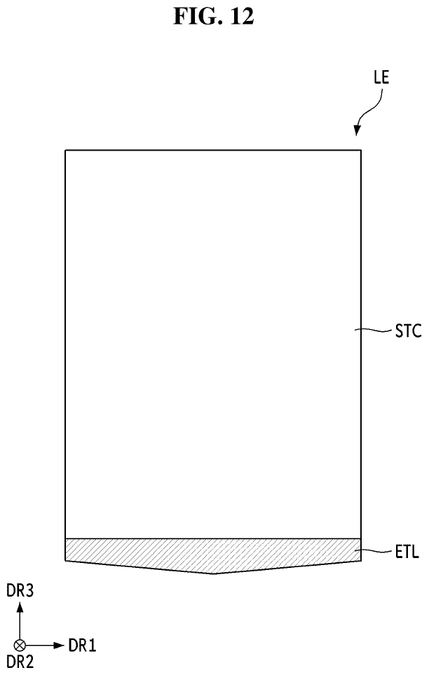

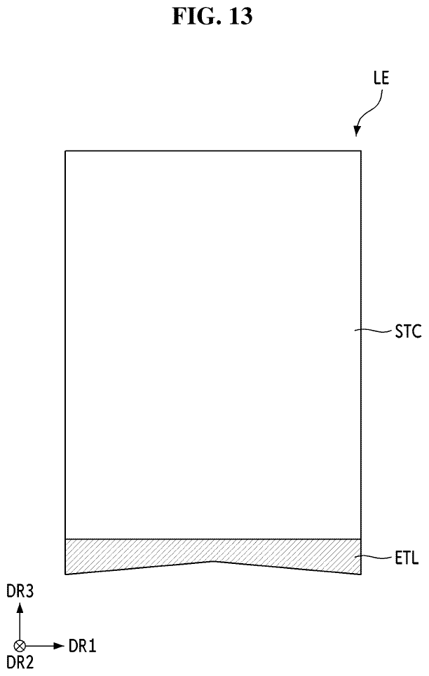

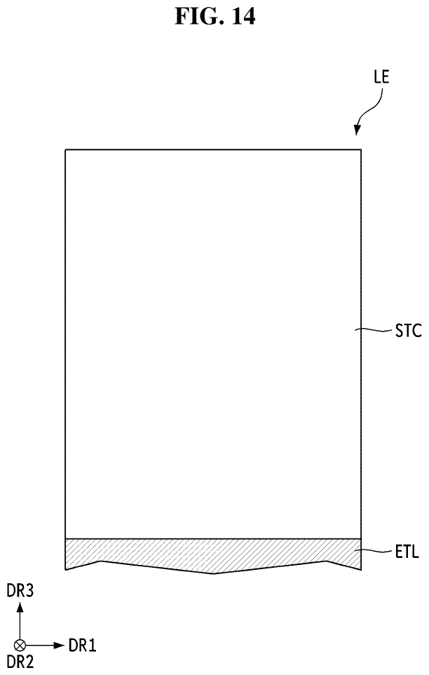

FIG. 11 is a cross-sectional view illustrating a light emitting element according to an embodiment. FIG. 12 is a cross-sectional view illustrating a light emitting element according to an embodiment. FIG. 13 is a cross-sectional view illustrating a light emitting element according to an embodiment. FIG. 14 is a cross-sectional view illustrating a light emitting element according to an embodiment. For example, FIGS. 11 to 14 illustrate different modified embodiments of an embodiment of FIG. 9 in relation to the electrode layer ETL of the light emitting element LE.

Referring to FIGS. 11 to 14, a lower surface of the electrode layer ETL may not be flat. For example, a lower surface of the electrode layer ETL may be uneven, and/or a lower surface of the electrode layer ETL may have a bend. Accordingly, a surface area of the lower surface of the electrode layer ETL may increase.

In an embodiment, the electrode layer ETL may have an irregularity structure including a plurality of projections protruding downward and valleys positioned between the projections as illustrated in FIG. 11 when viewed in cross section. In another embodiment, the electrode layer ETL may have a shape in which a thickness thereof increases from the edge to the center and accordingly, the center protrudes downward, as illustrated in FIG. 12, or may have a shape in which the thickness thereof increases from the center to the edge and accordingly, the edge protrudes downward, as illustrated in FIG. 13. In still another embodiment, the electrode layer ETL may have an inflection point at which a change direction of a thickness changes one or more times between the edge and the center, as illustrated in FIG. 14. As an example, the electrode layer ETL may have a shape including projections protruding downward at the edge and the center and a valley positioned between the projections. In addition, the electrode layer ETL may have various shapes in which a lower surface area thereof may increase.

The lower surface area of the electrode layer ETL increases, and accordingly, a lower surface area of the light emitting element LE may increase. Accordingly, when the light emitting element LE is mounted on the mounting surface of the electronic device, a contact area between an electrode (e.g., an electrode or a bonding pad on the mounting surface) of the electronic device connected to the light emitting element LE and the light emitting element LE may be increased, such that a separation rate of the light emitting element LE may be reduced and a quality of bonding between the electrode and the light emitting element LE may be improved.

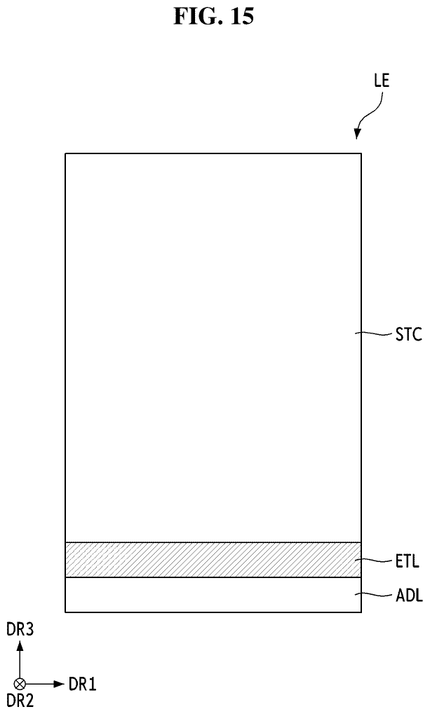

FIG. 15 is a cross-sectional view illustrating a light emitting element according to an embodiment. FIG. 15 illustrates a light emitting element LE including an additional component compared to FIG. 9.

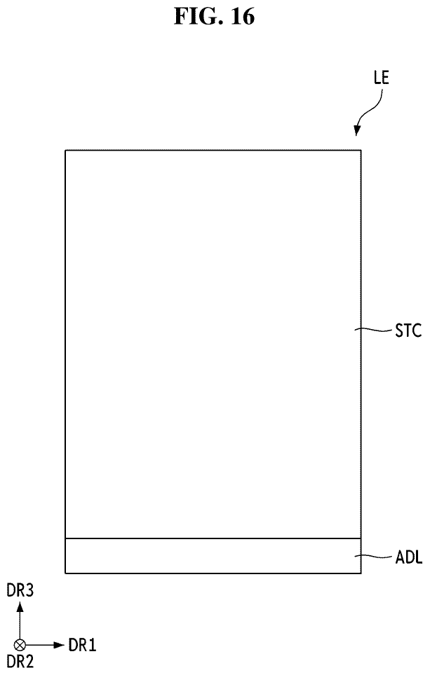

FIG. 16 is a cross-sectional view illustrating a light emitting element according to an embodiment. FIGS. 15 and 16 illustrate different embodiments in relation to the electrode layer ETL.

Referring to FIGS. 15 and 16, the light emitting element LE may further include an adhesive layer ADL disposed on the lower surface of the semiconductor stack STC. For example, the light emitting element LE may include an adhesive layer ADL disposed on the lower surface of the electrode layer ETL as illustrated in FIG. 15. Alternatively, the light emitting element LE may not include the electrode layer ETL as illustrated in FIG. 16, and may include an adhesive layer ADL disposed directly on the lower surface of the semiconductor stack STC.

The adhesive layer ADL may be disposed at the lowermost portion of the light emitting element LE. In an embodiment, the adhesive layer ADL may include a conductive adhesive. Accordingly, the adhesive layer ADL may be electrically connected to an electrode, a line, or the like, of the electronic device. Alternatively, the adhesive layer ADL may include a non-conductive adhesive. In this case, the light emitting element LE may be electrically connected to the electrode, the line, or the like, of the electronic device on a side surface or the like of the electrode layer ETL.

As in embodiments of FIGS. 15 and 16, the adhesive layer ADL is disposed at the lowermost portion of the light emitting element LE, and accordingly, the light emitting element LE may be more stably mounted on or fixed onto the mounting surface of the electronic device or the like. For example, the possibility that the light emitting element LE will be vertically mounted on the mounting surface of the electronic device or the like may be increased, and the light emitting element LE may be more stably fixed onto the mounting surface.

Embodiments in which the adhesive layer ADL is disposed below the semiconductor stack STC of the light emitting element LE in which an aspect ratio is greater than 1 have been illustrated in FIGS. 15 and 16, but embodiments are not limited thereto. For example, even in the case of the light emitting element LE in which the first semiconductor layer SEM1 has the reduced thickness and the aspect ratio of the semiconductor stack STC is 1 or less as in embodiments of FIGS. 1 to 8, the adhesive layer ADL may be selectively disposed on the lower surface of the semiconductor stack STC.

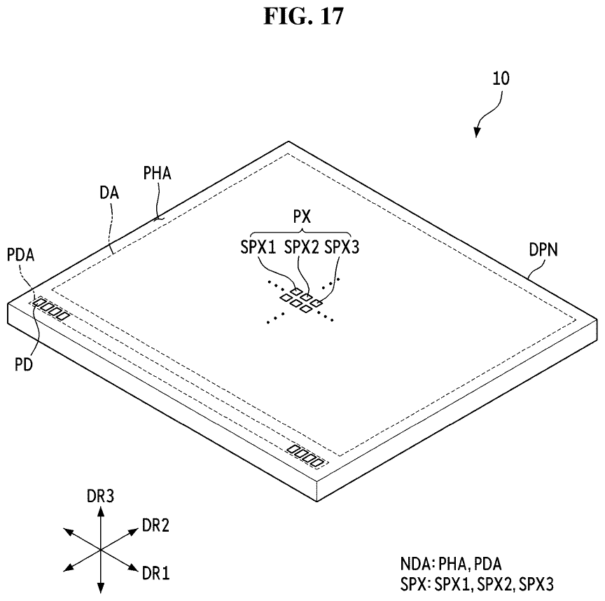

FIG. 17 is a perspective view illustrating a display device according to an embodiment.

Referring to FIG. 17, a display device 10 is a device that displays a moving image or a still image, and may be used as a display screen of various electronic devices. For example, the display device 10 may be used as a display screen of various electronic devices, such as televisions, laptop computers, monitors, billboards, and the Internet of Things (IOT), as well as portable electronic devices, such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). In addition, the display device 10 may be applied to other electronic devices such as a virtual reality (VR) device or an augmented reality (AR) device. For example, the display device 10 may be included in at least one of the electronic devices exemplified above or included in other types of electronic devices.

In an embodiment, the display device 10 may be a light emitting display device including light emitting elements LE. For example, the display device 10 may be an organic light emitting display device including organic light emitting diodes, a quantum dot light emitting display device including quantum dot light emitting layers, an inorganic light emitting display device including inorganic semiconductors, or a micro light emitting display device including micro light emitting diodes, such as micro or nano light emitting diodes (micro LEDs or nano LEDs).

Hereinafter, embodiments in which the display device 10 is a light emitting display device including micro or nano light emitting diodes will be described. However, a type, a size, or the like, of the light emitting element LE according to embodiments is not limited thereto.

The display device 10 may include a display panel DPN including a display area DA and a non-display area NDA. In an embodiment, the display panel DPN may have a quadrangular shape in plan view, but is not limited thereto. For example, the display panel DPN may have other polygonal shapes other than the quadrangular shape, a circular shape, an elliptical shape, or an irregular shape in plan view. The first direction DR1, the second direction DR2, and the third direction DR3 of FIG. 1 may be a transverse direction, a longitudinal direction, and a thickness direction of the display panel DPN, respectively.

The display device 10 may include pixels PX disposed in the display area DA. An image may be displayed in the display area DA by the pixels PX. For example, the pixels PX and lines (or portions of the lines) connected to the pixels PX may be disposed in the display area DA. In describing embodiments, the term “connection” may include the meaning of an electrical connection and/or a physical connection. An embodiment in which the display area DA has a quadrangular shape in plan view has been illustrated in FIG. 1, but a shape of the display area DA is not limited thereto.

Each pixel PX may include a plurality of sub-pixels SPX. As an example, each pixel PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. In an embodiment, the first sub-pixel SPX1 may be a red sub-pixel emitting red light, the second sub-pixel SPX2 may be a green sub-pixel emitting green light, and the third sub-pixel SPX3 may be a blue sub-pixel emitting blue light. Types, the number, a ratio, an arrangement structure, and the like, of sub-pixels SPX constituting each pixel PX may also be variously changed according to embodiments.

Each of the sub-pixels SPX may have a quadrangular shape, such as a rectangular shape or a rhombic shape, in plan view, but is not limited thereto. For example, each of the sub-pixels SPX may have other polygonal shapes (e.g., a hexagonal shape or a diamond shape), a circular shape, an elliptical shape, or other shapes in plan view.

The sub-pixels SPX may be connected to a driving circuit and a power supply unit through lines and/or pads PD formed inside the display panel DPN to receive driving signals and driving voltages. As an example, the sub-pixels SPX may receive scan signals (or clock signals), data signals (or digital data), a first driving voltage (e.g., a high potential pixel voltage or an anode voltage), and a second driving voltage (e.g., a low potential pixel voltage or a cathode voltage). The sub-pixels SPX may emit light in response to the driving signals and the driving voltages.

In an embodiment, at least a portion of the driving circuit (e.g., at least some of components of the driving circuit) supplying the driving signals to the sub-pixels SPX may be formed in the display panel DPN or disposed on the non-display area NDA of the display panel DPN. In another embodiment, the driving circuit may be disposed outside the display panel DPN and electrically connected to a plurality of pads PD disposed in a pad area PDA. In an embodiment, the power supply unit supplying the driving voltages to the sub-pixels SPX may be disposed outside the display panel DPN (e.g., on a circuit board electrically connected to the display panel DPN) and electrically connected to the plurality of pads PD disposed in the pad area PDA. However, positions of the driving circuit and the power supply unit, connection structures between each of the driving circuit and the power supply unit and the sub-pixels SPX, or the like, may be changed according to embodiments.

Each sub-pixel SPX may include at least one light emitting element LE such as the light emitting element LE according to at least one of embodiments described with reference to FIGS. 1 to 16. Each sub-pixel SPX may further include a pixel circuit electrically connected to the light emitting element LE. The driving signals and the first driving voltage of the sub-pixels SPX may be applied to the pixel circuits of each of the sub-pixels SPX, and the second driving voltage of the sub-pixels SPX may be applied to the light emitting elements LE through a common electrode connected to the light emitting elements LE of the sub-pixels SPX. The second driving voltage applied to the light emitting elements LE may also be referred to as a “common voltage”.

The non-display area NDA may be an area where an image is not displayed. The non-display area NDA may be disposed around the display area DA. As an example, the non-display area NDA may be disposed at an edge of the display panel DPN to surround the display area DA.

The non-display area NDA may include the pad area PDA and a peripheral area PHA. In the non-display area NDA, lines (or a portion of the lines) connected to the sub-pixels SPX and the pads PD may be disposed.

The pads PD may be disposed in the pad area PDA. The pads PD may be connected to a circuit board (not illustrated) through conductive balls, wires, or other conductive connection members. In addition, the pads PD may be electrically connected to the sub-pixels SPX. Driving signals and driving voltages for driving the display panel DPN may be supplied from the circuit board to the display device 10 through the pads PD.

The pad area PDA may be disposed at at least one end (e.g., a lower end) of the display panel DPN. The pad area PDA may include the pads PD connected to an external circuit board. The pads PD may be electrically connected to the sub-pixels SPX through respective connection lines inside the display panel DPN. In an embodiment, when the driving circuit including at least one of a gate driver, a data driver, and a timing controller is disposed inside the display panel DPN and/or on the non-display area NDA, at least some of the pads PD may be connected to the driving circuit to transmit the driving signals and/or the driving voltages for driving the driving circuit.

The peripheral area PHA may be the remaining area of the non-display area NDA excluding the pad area PDA. The peripheral area PHA may surround the display area DA. The lines connected to the pixels PX and the pads PD may pass through the peripheral area PHA.

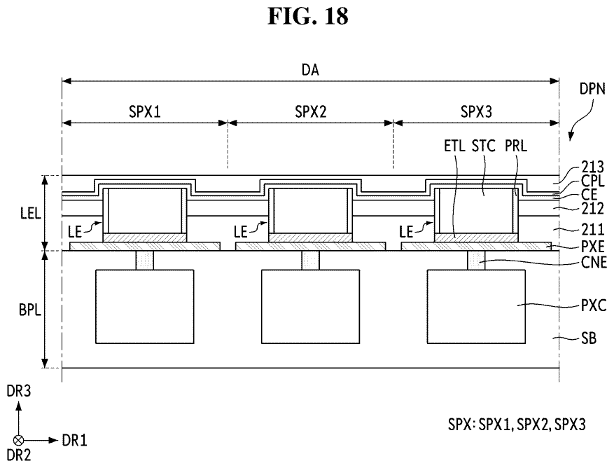

FIG. 18 is a cross-sectional view illustrating a display device according to an embodiment. For example, FIG. 18 illustrates a portion of the display panel DPN included in the display device 10 of FIG. 17, and illustrates a schematic cross section of a first sub-pixel SPX1, a second sub-pixel SPX2, and a third sub-pixel SPX3 that constitute one pixel PX among the sub-pixels SPX disposed in the display area DA.

Referring to FIGS. 17 and 18, the display device 10 may include a backplane substrate BPL and a light emitting element layer LEL disposed on the backplane substrate BPL. The backplane substrate BPL may also be referred to as a “lower substrate” or a “backplane layer”. FIG. 18 illustrates the display panel DPN having a light emitting diode on silicon (LEDoS) structure in which light emitting diodes are disposed as the light emitting elements LE on the backplane substrate BPL formed by a semiconductor process using a silicon wafer (e.g., a backplane substrate formed as a semiconductor circuit substrate). However, embodiments are not limited thereto. For example, the backplane substrate BPL may be a thin film transistor substrate in which thin film transistors included in a pixel circuit PXC and the like are formed on a backplane substrate of another type or structure, for example, a base substrate such as a glass substrate or a polymer film. In addition, embodiments may be applied to display devices of other types and/or structures or applied to electronic devices of other types and/or structures such as illumination devices.

In an embodiment, the display device 10 may further include additional components. As an example, the display device 10 may further include at least one of a color filter layer, a protective layer, and an optical structure (e.g., a micro lens array covering the light emitting elements LE of the sub-pixels SPX) disposed on the light emitting element layer LEL.

In an embodiment, when at least one of the light emitting elements LE of the first sub-pixel SPX1, the second sub-pixel SPX2, and the third sub-pixel SPX3 emits light of a different wavelength (or a different color) from an emission wavelength (or an emission color) of a corresponding sub-pixel SPX, the display device 10 may further include a light conversion layer disposed on the light emitting element layer LEL and converting a wavelength of the light emitted from the light emitting element LE of at least one sub-pixel SPX. In an embodiment, when the light emitting elements LE of the first sub-pixel SPX1, the second sub-pixel SPX2, and the third sub-pixel SPX3 emit light of a first color, light of a second color, and light of a third color corresponding to emission wavelengths of the respective sub-pixels SPX, the display device 10 may not include the light conversion layer.

The backplane substrate BPL may include a base substrate SB, pixel circuits PXC of the sub-pixels SPX, and connection electrodes CNE (also referred to as “first connection electrodes” or “through electrodes”). In an embodiment, the backplane substrate BPL may be formed by a semiconductor process using a silicon wafer. For example, the base substrate SB may be a silicon wafer. In an embodiment, the base substrate SB may be made of single crystal silicon.

The base substrate SB and the backplane substrate BPL including the base substrate SB may include the display area DA and the non-display area NDA of FIG. 17. The pixel circuits PXC and the connection electrodes CNE may be disposed in the display area DA within the backplane substrate BPL. The pads PD of FIG. 17 may be disposed inside or on the backplane substrate BPL. The pads PD may be disposed in the non-display area NDA.

Schematic positions of the pixel circuits PXC disposed within the backplane substrate BPL and illustrative connection structures between the pixel circuits PXC and the light emitting elements LE have been schematically illustrated in FIG. 18. The pixel circuit PXC of each of the sub-pixels SPX may have various structures according to embodiments, and may include circuit elements constituting each pixel circuit PXC (e.g., circuit elements of the pixel circuit PXC including a driving transistor and a capacitor of each sub-pixel SPX). For example, the backplane substrate BPL may include electrodes or conductive patterns constituting circuit elements constituting each pixel circuit PXC and contact terminals or lines connected to the circuit elements. In addition, the backplane substrate BPL may include a plurality of insulating layers disposed around the electrodes, the conductive patterns, the contact terminals, and/or the lines.

In an embodiment, each of the sub-pixels SPX may include a pixel circuit PXC and a light emitting element LE electrically connected to the pixel circuit PXC. The pixel circuit PXC may control a driving current flowing to the light emitting element LE of each sub-pixel SPX in response to driving signals input from the outside.

The pixel circuit PXC of each of the sub-pixels SPX may be electrically connected to a pixel electrode PXE (also referred to as an “electrode” or a “first electrode”) of the corresponding sub-pixel SPX through the connection electrode CNE, and may be electrically connected to a light emitting element LE of the corresponding sub-pixel SPX through the pixel electrode PXE. In an embodiment, each of the pixel circuits PXC may include a complementary metal oxide semiconductor (CMOS) circuit formed using a semiconductor process. As an example, each of the pixel circuits PXC may include at least one transistor and at least one capacitor formed using a semiconductor process. The driving signals and the first driving voltage (e.g., one of an anode voltage and a cathode voltage) of the sub-pixels SPX may be applied to the pixel circuit PXC of each of the sub-pixels SPX, and the second driving voltage (e.g., the other of the anode voltage and the cathode voltage or a common voltage) of the sub-pixels SPX may be applied to the light emitting elements LE of the sub-pixels SPX through a common electrode CE electrically connected to the light emitting elements LE of the sub-pixels SPX.

The connection electrodes CNE may penetrate through an insulating layer covering the pixel circuits PXC within the backplane substrate BPL, and may connect the pixel circuits PXC and the pixel electrodes PXE of the sub-pixels SPX to each other. For example, each of the connection electrodes CNE may be electrically connected between at least one circuit element (or a contact terminal connected to the circuit element) included in the pixel circuit PXC of the corresponding sub-pixel SPX and the light emitting element LE of the corresponding sub-pixel SPX. Each of the connection electrodes CNE may include a conductive material. As an example, each of the connection electrodes CNE may include copper (Cu), titanium (Ti), silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or mixtures thereof, but is not limited thereto.

The backplane substrate BPL may further include lines electrically connected to the sub-pixels SPX and the pads PD. For example, the backplane substrate BPL may include signal lines and power lines that are electrically connected to the sub-pixels SPX. The signal lines are lines connected between the pads PD or the driving circuit and the sub-pixels SPX to transmit the scan signals (or the clock signals) and the data signals (or the digital data) to the sub-pixels SPX. The power lines are lines transmitting the first driving voltage and the second driving voltage to the sub-pixels SPX.

In an embodiment, a first power line transmitting the first driving voltage may be electrically connected between at least one pad PD disposed in the pad area PDA and the pixel circuits PXC disposed in the display area DA, and may be formed within the backplane substrate BPL. The first power line may transmit the first driving voltage applied from the at least one pad PD to the pixel circuits PXC.

In an embodiment, a second power line transmitting the second driving voltage, for example, the common voltage, may be electrically connected between at least one other pad PD disposed in the pad area PDA and the common electrode CE (or second electrodes of the sub-pixels SPX) disposed in the display area DA. As an example, the common electrode CE may be electrically connected to a backplane power line formed within the backplane substrate BPL in the display area DA and/or the peripheral area PHA, and may be electrically connected to at least one pad PD disposed in the pad area PDA through the backplane power line.

The light emitting element layer LEL may include light emitting elements LE, electrodes and/or lines electrically connected to the light emitting elements LE, and insulating layers disposed around the light emitting elements LE. For example, the light emitting element layer LEL may include pixel electrodes PXE disposed on the backplane substrate BPL, light emitting elements LE disposed on the pixel electrodes PXE, and a common electrode CE disposed on the light emitting elements LE. In addition, the light emitting element layer LEL may further include a first insulating layer 211 and a second insulating layer 212 surrounding the light emitting elements LE, a capping layer CPL covering the common electrode CE, and a third insulating layer 213 covering the capping layer CPL. In an embodiment, the first insulating layer 211 and the second insulating layer 212 may be integrated with each other as one insulating layer. In an embodiment, the capping layer CPL and the third insulating layer 213 may be integrated with each other as one insulating layer or protective layer.

In an embodiment, the light emitting element layer LEL may further include additional components for improving light emitting characteristics (e.g., light efficiency) of the sub-pixels SPX. As an example, the light emitting element layer LEL may further include a reflective layer (e.g., a side surface reflective layer) and/or a light blocking layer surrounding the light emitting elements LE of the sub-pixels SPX or disposed between the light emitting elements LE.

The pixel electrodes PXE may be disposed in respective sub-pixel areas where the respective sub-pixels SPX are disposed. The pixel electrodes PXE may be electrically connected to the respective pixel circuits PXC. Each of the pixel electrodes PXE may include a conductive material, and may be formed as a single layer or multiple layers.

The light emitting elements LE may be disposed on the respective pixel electrodes PXE. For example, the light emitting element LE of the first sub-pixel SPX1, the light emitting element LE of the second sub-pixel SPX2, and the light emitting element LE of the third sub-pixel SPX3 may be disposed on the pixel electrode PXE of the first sub-pixel SPX1, the pixel electrode PXE of the second sub-pixel SPX2, and the pixel electrode PXE of the third sub-pixel SPX3, respectively.

In an embodiment, the first sub-pixel SPX1, the second sub-pixel SPX2, and the third sub-pixel SPX3 may include light emitting elements LE corresponding to their respective emission wavelengths or emission colors. For example, the first sub-pixel SPX1 may include a light emitting element LE of the first color emitting the light of the first color (e.g., red light), the second sub-pixel SPX2 may include a light emitting element LE of the second color emitting the light of the second color (e.g., green light), and the third sub-pixel SPX3 may include a light emitting element LE of the third color emitting the light of the third color (e.g., blue light).

However, embodiments are not limited thereto. As an example, the first sub-pixel SPX1, the second sub-pixel SPX2, and the third sub-pixel SPX3 may include light emitting elements LE that emit light of the same color (e.g., blue light or white light), and a light conversion layer and/or a color filter converting a wavelength or a color of light emitted from the light emitting element LE of the corresponding sub-pixel SPX may be disposed above at least one of the light emitting elements LE of the first sub-pixel SPX1, the second sub-pixel SPX2, and the third sub-pixel SPX3.

In an embodiment, each of the light emitting elements LE may include a semiconductor stack STC, an electrode layer ETL disposed below the semiconductor stack STC, and a protective layer PRL covering a side surface of the semiconductor stack STC. However, embodiments are not limited thereto. For example, as described in embodiments of FIGS. 1 to 16, each of the light emitting elements LE may include at least a semiconductor stack STC, and may further include at least one of an electrode layer ETL and a protective layer PRL or may not include the electrode layer ETL and the protective layer PRL. One of the first semiconductor layer SEM1 and the second semiconductor layer SEM2 of the semiconductor stack STC may be electrically connected to the pixel electrode PXE. The other of the first semiconductor layer SEM1 and the second semiconductor layer SEM2 of the semiconductor stack STC may be electrically connected to the common electrode CE.

At least one sub-pixel SPX may include the light emitting element LE according to at least one of embodiments described with reference to FIGS. 1 to 16. For example, the light emitting element LE may include the semiconductor stack STC including the first semiconductor layer SEM1, the active layer MQW, and the second semiconductor layer SEM2 that are sequentially disposed in the thickness direction.

The light emitting element LE may have a structure with improved stability. For example, the first semiconductor layer SEM1 of the light emitting element LE may be etched to have a limited thickness, or the light emitting element LE may include at least one of the electrode layer ETL, the reflective layer RFL, and the adhesive layer ADL disposed on the lower surface of the semiconductor stack STC. Alternatively, the first semiconductor layer SEM1 of the light emitting element LE may be etched to have a limited thickness, and the light emitting element LE may include at least one of the electrode layer ETL, the reflective layer RFL, and the adhesive layer ADL disposed on the lower surface of the semiconductor stack STC.

In an embodiment, when the light emitting element LE includes the first semiconductor layer SEM1 having the limited thickness, the first semiconductor layer SEM1 of the light emitting element LE may have a thickness of 100 nm or less or have a thickness less than ⅙ of the thickness of the semiconductor stack STC. In an embodiment, the first semiconductor layer SEM1 may be an n-type semiconductor layer including an n-type semiconductor, and may be grown to a sufficient thickness on a manufacturing substrate for forming the light emitting element LE and then etched by a partial thickness to have a limited thickness. In an embodiment, the thickness of the semiconductor stack STC of the light emitting element LE may be smaller than or equal to a width of the semiconductor stack STC. Accordingly, the light emitting element LE may have a low center of gravity.

In an embodiment, when the light emitting element LE further includes at least one of the electrode layer ETL and the reflective layer RFL disposed on the lower surface of the semiconductor stack STC, at least one of the electrode layer ETL and the reflective layer RFL may include a conductive material having a density higher than a density of a semiconductor material included in the semiconductor stack STC. Accordingly, the light emitting element LE may have a low center of gravity. The first semiconductor layer SEM1 of the light emitting element LE including the electrode layer ETL and/or the reflective layer RFL may have a thickness limited as in the range exemplified above or may have a thickness greater than or equal to the range. An aspect ratio of the semiconductor stack STC of the light emitting element LE including the electrode layer ETL and/or the reflective layer RFL may be 1 or less or be greater than 1.

In an embodiment, when the light emitting element LE includes the adhesive layer ADL disposed at the lowermost portion, a base surface seating property of the light emitting element LE may be further improved.

The light emitting elements LE of the sub-pixels SPX may be directly disposed on the respective pixel electrodes PXE. As an example, the pixel electrode PXE of each of the sub-pixels SPX may be directly bonded to the electrode layer ETL of the light emitting element LE.

However, embodiments are not limited thereto. For example, the pixel electrode PXE of each of the sub-pixels SPX and the light emitting element LE may also be bonded to each other using a separate bonding layer or electrode (e.g., a bonding layer or a bonding electrode including a bonding metal). In addition, each of the light emitting elements LE may or may not include the electrode layer ETL.

Each of the first insulating layer 211 and the second insulating layer 212 may include an organic insulating material or an inorganic insulating material, and may be formed as a single layer or multiple layers. The first insulating layer 211 and the second insulating layer 212 may be filled between the light emitting elements LE, and may partially or entirely surround side surfaces of the light emitting elements LE. An embodiment in which the first insulating layer 211 and the second insulating layer 212 are formed at a height smaller than or equal to a height of the light emitting elements LE has been illustrated in FIG. 18, but embodiments are not limited thereto. For example, the second insulating layer 212 may be formed at a greater height than the light emitting elements LE. In this case, the second insulating layer 212 may include openings partially or entirely exposing upper surfaces of the light emitting elements LE, and the common electrode CE may be electrically connected to the light emitting elements LE by the openings. In an embodiment, the second insulating layer 212 may be omitted. For example, when the first insulating layer 211 is formed at a height enough to alleviate a step caused by the light emitting elements LE, the second insulating layer 212 may be omitted.

The common electrode CE may be disposed on the light emitting elements LE and the second insulating layer 212 (or the first insulating layer 211). In an embodiment, the common electrode CE may be a common layer formed in common in the sub-pixels SPX. For example, the common electrode CE may be entirely formed in the display area DA. However, embodiments are not limited thereto. For example, the sub-pixels SPX may include respective second electrodes that are formed individually. The second electrode of each of the sub-pixels SPX may be electrically connected to the light emitting element LE of each of the sub-pixels SPX.

The common electrode CE may include a conductive material, and may be formed as a light transmitting electrode so that light emitted from the light emitting elements LE may be transmitted therethrough. For example, the common electrode CE may be made of a transparent conductive material (e.g., transparent conductive oxide) such as indium tin oxide (ITO) or indium zinc oxide (IZO) capable of transmitting light therethrough.

The capping layer CPL may be disposed on the common electrode CE. The capping layer CPL may include an inorganic insulating material (e.g., silicon oxide (SiOₓ), silicon nitride (SiNₓ), silicon oxynitride (SiOₓN_{y}), aluminum oxide (AlₓO_{y}), or other inorganic insulating materials) appropriate for protecting the light emitting elements LE and the common electrode CE. In an embodiment, the capping layer CPL may be omitted or integrated with the third insulating layer 213.

The third insulating layer 213 may include an organic insulating material or an inorganic insulating material, and may be formed as a single layer or multiple layers. In an embodiment, an upper surface of the third insulating layer 213 may be flat. As an example, the third insulating layer 213 may include a material having high flatness (e.g., an organic insulating material), and/or may be formed at a thickness enough for the upper surface to become flat. Alternatively, the third insulating layer 213 may be planarized by a planarization process (e.g., a chemical mechanical polishing (CMP) process, etc.). Accordingly, an upper surface of the light emitting element layer LEL may be planarized.

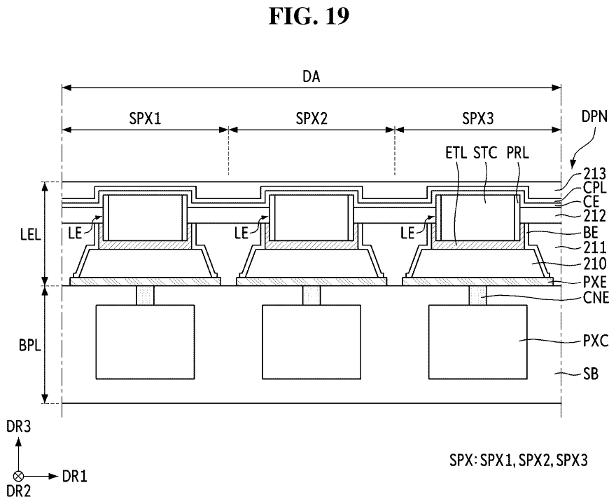

FIG. 19 is a cross-sectional view illustrating a display device according to an embodiment. For example, FIG. 19 illustrates a portion of the display panel DPN included in the display device 10 of FIG. 17, and illustrates a schematic cross section of a first sub-pixel SPX1, a second sub-pixel SPX2, and a third sub-pixel SPX3 that constitute one pixel PX among the sub-pixels SPX disposed in the display area DA. FIG. 19 illustrates a display device 10 different from that of FIG. 18 in a structure of the light emitting element layer LEL.

Referring to FIG. 19, the light emitting element layer LEL of the display panel DPN may further include an organic layer 210 and connection electrodes BE (also referred to as “second connection electrodes” or “bridge electrodes”) that are disposed on the pixel electrodes PXE. The light emitting elements LE may be disposed on the organic layer 210, and may be electrically connected to the respective pixel electrodes PXE by the respective connection electrodes BE.

In an embodiment, the organic layer 210 may be disposed on a portion of each of the pixel electrodes PXE including a central portion of each of the pixel electrodes PXE. The organic layer 210 may expose the other portion of each of the pixel electrodes PXE such as an edge portion of each of the pixel electrodes PXE. In another embodiment, the organic layer 210 may be entirely formed in the display area DA, and may include openings (e.g., contact holes filled with the connection electrodes BE) exposing portions of the pixel electrodes PXE.

The organic layer 210 may temporarily fix or adhere the light emitting elements LE in order to prevent the light emitting elements LE from being inclined and falling over or collapsing in a process of dropping or transferring the light emitting elements LE onto a mounting surface (e.g., an upper surface of the backplane substrate BPL on which the pixel electrodes PXE are formed). For example, the organic layer 210 may be a film for temporarily adhering the light emitting elements LE onto the pixel electrodes PXE. A thickness of the organic layer 210 may be greater than a thickness of each of the pixel electrodes PXE so that the temporary adhering of the light emitting elements LE onto the pixel electrodes PXE is easy.

In an embodiment, the organic layer 210 may be made of a photosensitive material such as a photoresist. Alternatively, the organic layer 210 may be formed as another organic film made of an acrylic resin, an epoxy resin, a phenolic resin, a polyamide resin, a polyimide resin, or the like.

Each of the connection electrodes BE may connect the light emitting element LE and the pixel electrode PXE of each sub-pixel SPX to each other. For example, each of the connection electrodes BE may be electrically connected to the electrode layer ETL on a side surface of the electrode layer ETL of each of the light emitting elements LE. In an embodiment, the electrode layer ETL may have a shape in which it extends above the protective layer PRL covering the side surface of the semiconductor stack STC. Accordingly, a contact area between the electrode layer ETL and the connection electrode BE may be secured or expanded. In addition, each of the connection electrodes BE may be electrically connected to the pixel electrode PXE in a portion of the pixel electrode PXE that is not covered by the organic layer 210 (or a contact hole penetrating through the organic layer 210).

Each of the connection electrodes BE may include a conductive material. As an example, each of the connection electrodes BE may include any one of molybdenum (Mo), aluminum (Al), chromium (Cr), gold (Au), titanium (Ti), nickel (Ni), neodymium (Nd), and copper (Cu) or a transparent conductive material such as ITO or IZO. In an embodiment, the connection electrodes BE may include a material capable of sputtering and wet etching, and may be formed by sputtering and wet etching.

In an embodiment, when each of the connection electrodes BE is made of a metal material having a high reflectivity, such as aluminum (Al), light that has traveled in a lateral direction of the light emitting elements LE among light generated from the light emitting elements LE may be reflected by the connection electrodes BE and travel in an upward direction of each of the light emitting elements LE. Accordingly, light efficiency of the sub-pixels SPX may be improved.

In an embodiment, the light emitting elements LE may be dropped or transferred onto the mounting surface using a laser lift-off (LLO) method or other methods, and a connection process or a bonding process for stably connecting the light emitting elements LE and the pixel electrodes PXE to each other may be then performed. As an example, the light emitting elements LE may be dropped or transferred onto the organic layer 210 using a laser lift-off method, and the connection electrodes BE connecting the light emitting elements LE to the respective pixel electrodes PXE may be then formed. Alternatively, when the light emitting elements LE are directly disposed on the respective pixel electrodes PXE as in an embodiment of FIG. 18, the light emitting elements LE may be dropped or transferred onto the respective pixel electrodes PXE using a laser lift-off method or other methods, and a bonding process for stably bonding the light emitting elements LE and the pixel electrodes PXE to each other may be then performed.

As described above, the light emitting elements LE according to embodiments may have a low center of gravity, and may have improved stability. Accordingly, the light emitting elements LE may be stably disposed on the mounting surface.

According to embodiments, stability and a quality of the transfer or the bonding of the light emitting elements LE may be improved. For example, in a transfer process, a bonding process, or the like, of the light emitting elements LE, a transfer defect or a bonding defect of the light emitting elements LE that may occur because the light emitting elements LE are not appropriately seated or aligned on the transfer surface or the mounting surface may be prevented or reduced. Accordingly, a yield of the electronic device including the light emitting elements LE may be improved. For example, image quality non-uniformity or a lighting defect of the display device 10 due to the transfer defect, the bonding defect, or the like, of the light emitting elements LE may be prevented, and a yield of the display device 10 may be improved.

With the light emitting element LE according to embodiments and the display device 10 including the same, the light emitting element LE may be stably disposed on the backplane substrate BPL of the display device 10, and the light emitting element LE and the backplane substrate BPL may be stably connected to each other. Accordingly, a utilization rate of the light emitting element LE may be increased, and a yield of the display device 10 may be improved.

The display device according to one embodiment of the present disclosure can be applied to various electronic devices. The electronic device according to the one embodiment of the present disclosure includes the display device described above, and may further include modules or devices having additional functions in addition to the display device.

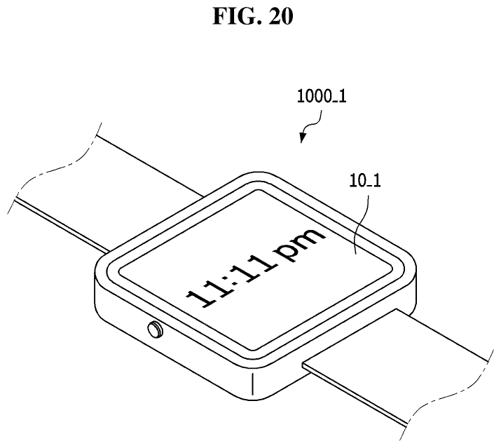

FIG. 20 is a view illustrating a smart watch including the display device according to an embodiment.

Referring to FIG. 20, a display device 10_1 according to an embodiment may be applied to a smart watch 1000_1, which is one of smart devices.

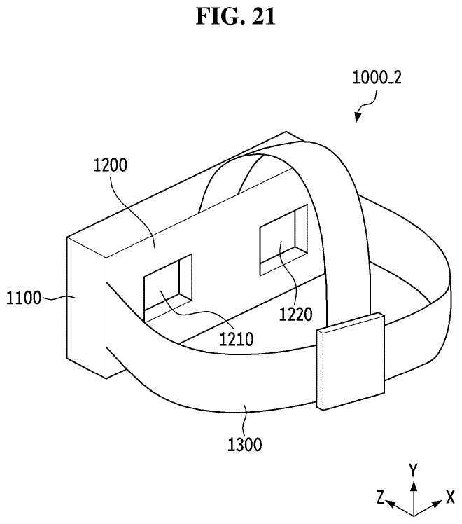

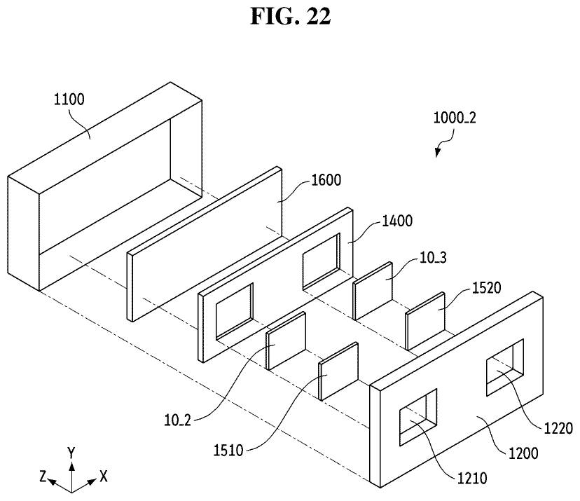

FIGS. 21 and 22 are views illustrating a head mounted display device including the display device according to an embodiment.

Referring to FIGS. 21 and 22, a head mounted display device 1000_2 according to an embodiment may be a virtual reality device. The head mounted display device 1000_2 includes a first display device 10_2, a second display device 10_3, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to a user's right eye.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and disposed between the second display device 10_3 and the control circuit board 1600. The middle frame 1400 serves to support and fix the first display device 10_2, the second display device 10_3, and the control circuit board 1600.

The control circuit board 1600 may be disposed between the middle frame 1400 and the display device housing portion 1100. The control circuit board 1600 may be connected to the first display device 10_2 and the second display device 10_3 through a connector. The control circuit board 1600 may convert an image source input from the outside into video data, and transmit the video data to the first display device 10_2 and the second display device 10_3 through the connector.

The control circuit board 1600 may transmit video data corresponding to a left eye image optimized for the user's left eye to the first display device 10_2 and transmit video data corresponding to a right eye image optimized for the user's right eye to the second display device 10_3. Alternatively, the control circuit board 1600 may transmit the same video data to the first display device 10_2 and the second display device 10_3.

The display device housing portion 1100 serves to house the first display device 10_2, the second display device 10_3, the middle frame 1400, the first optical member 1510, the second optical member 1520, and the control circuit board 1600.

The housing portion cover 1200 is disposed to cover opened one surface of the display device housing portion 1100. The housing portion cover 1200 may include the first eyepiece 1210 on which the user's left eye is disposed and the second eyepiece 1220 on which the user's right eye is disposed. It has been illustrated in FIGS. 21 and 22 that the first eyepiece 1210 and the second eyepiece 1220 are separately disposed, but embodiments are not limited thereto. As an example, the first eyepiece 1210 and the second eyepiece 1220 may be merged as one eyepiece.

The first eyepiece 1210 may be aligned with the first display device 10_2 and the first optical member 1510, and the second eyepiece 1220 may be aligned with the second display device 10_3 and the second optical member 1520. A user may view an image of the first display device 10_2 magnified as a virtual image by the first optical member 1510 through the first eyepiece 1210, and may view an image of the second display device 10_3 magnified as a virtual image by the second optical member 1520 through the second eyepiece 1220.

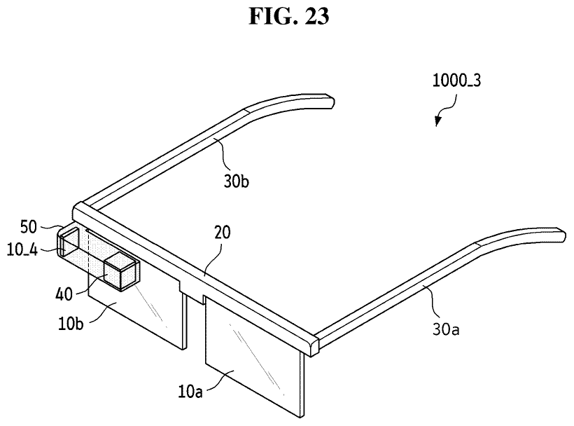

The head mounted band 1300 serves to fix the display device housing portion 1100 to a user's head so that the first eyepiece 1210 and the second eyepiece 1220 of the housing portion cover 1200 may be maintained in a state where they are disposed on the user's left eye and right eye, respectively. When the display device housing portion 1100 is implemented to have a light weight and a small size, the head mounted display device 1000_2 may include an eyeglasses frame as illustrated in FIG. 23 instead of the head mounted band 1300.

In addition, the head mounted display device 1000_2 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 23 is a view illustrating a head mounted display device including the display device according to an embodiment.

Referring to FIG. 23, a head mounted display device 1000_3 according to an embodiment may be an eyeglasses-type device. The head mounted display device 1000_3 according to an embodiment may include a display device 10_4, a left eye lens 10a, a right eye lens 10b, a support frame 20, eyeglasses frame legs 30a and 30b, a reflective member 40, and a display device housing portion 50.

It has been illustrated in FIG. 23 that the head mounted display device 1000_3 is an eyeglasses-type display device including the eyeglasses frame legs 30a and 30b, but embodiments are not limited thereto. For example, the head mounted display device 1000_3 may be applied in various forms in other electronic devices.

The display device housing portion 50 may include the display device 10_4 and the reflective member 40 (or a light path conversion member). An image displayed on the display device 10_4 may be reflected by the reflective member 40 and provided to a user's right eye through the right eye lens 10b. For this reason, a user may view an augmented reality image in which a virtual image displayed on the display device 10_4 through his/her right eye and a real image seen through the right eye lens 10b are combined with each other. In an embodiment, the display device housing portion 50 may include an optical member disposed between the display device 10_4 and the reflective member 40. An image displayed on the display device 10_4 may be magnified by the optical member, converted in an optical path by the reflective member 40, and provided to the user's right eye through the right eye lens 10b.

It has been illustrated in FIG. 23 that the display device housing portion 50 is disposed at a right end of the support frame 20, but an embodiment of the present disclosure is not limited thereto. For example, the display device housing portion 50 may be disposed at a left end of the support frame 20. In this case, an image displayed on the display device 10_4 may be reflected by the reflective member 40 and provided to a user's left eye through the left eye lens 10a. Accordingly, the user may view an image displayed on the display device 10_4 through his/her left eye. Alternatively, the display device housing portions 50 may be disposed at both the left and right ends of the support frame 20. In this case, the user may view an image displayed on the display device 10_4 through both his/her left and right eyes.

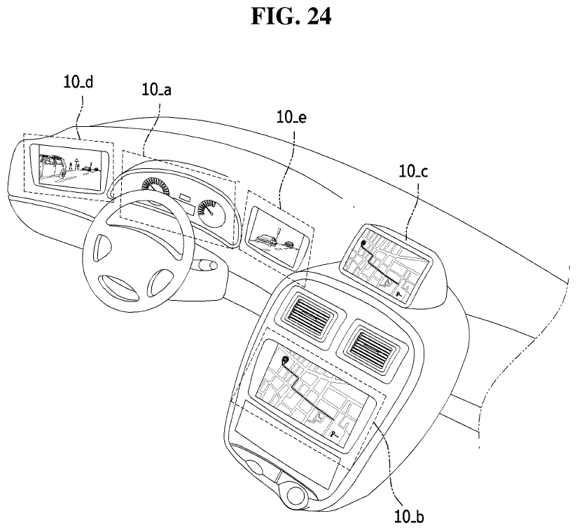

FIG. 24 is a view illustrating an instrument board and a center fascia of a vehicle including the display devices according to an embodiment. A vehicle to which display devices 10_a, 10_b, 10_c, 10_d, and 10_e according to an embodiment are applied is illustrated in FIG. 24.

Referring to FIG. 24, the display devices 10_a, 10_b, and 10_c according to an embodiment may be applied to an instrument board of the vehicle, applied to a center fascia of the vehicle, or applied to a center information display (CID) disposed on a dashboard of the vehicle. In addition, the display device 10_d and 10_e according to an embodiment may be applied to a room mirror display substituting for a side-view mirror of the vehicle.

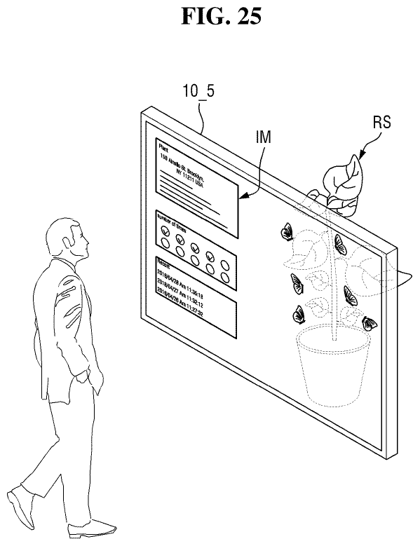

FIG. 25 is a view illustrating a transparent display device including the display device according to an embodiment.

Referring to FIG. 25, a display device 10_5 according to an embodiment may be applied to a transparent display device. The transparent display device may transmit light therethrough while displaying an image IM. Therefore, a user positioned on a front surface of the transparent display device may not only view the image IM displayed on the display device 10_5, but also see an object RS or a background positioned on a rear surface of the transparent display device. When the display device 10_5 is applied to the transparent display device, a substrate of the display device 10_5 may include a light transmitting portion capable of transmitting light therethrough or may be made of a material capable of transmitting light therethrough.

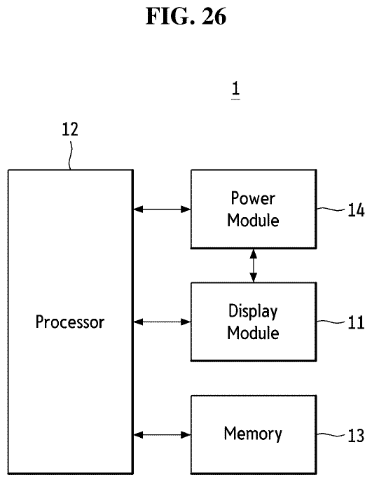

FIG. 26 is a block diagram of an electronic device according to one embodiment of the present disclosure.

Referring to FIG. 26, the electronic device 1 according to one embodiment of the present disclosure may include a display module 11, a processor 12, a memory 13, and a power module 14.

The display module 11 may include a display panel for displaying an image. For example, the display module 11 may include the display device 10 according to at least one of the embodiments described above.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. The processor 12 may transmit an image data signal and/or an input control signal stored in the memory 13 to the display module 11. For example, the processor 12 executes an application stored in the memory 13, the image data signal and/or the input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 1 according to the one embodiment of the present disclosure may be included in the display device according to the embodiments of the present disclosure. In addition, some modules of the individual modules functionally included in one module may be included in the display device 1, and other modules may be provided separately from the display device 1. For example, the display device 1 may include the display module 11, and the processor 12, the memory 13, and the power module 14 may be provided in the form of other devices within the electronic device 1 other than the display device 1.

In concluding the detailed description, those skilled in the art will appreciate that many variations and modifications can be made to the embodiments without substantially departing from the principles described herein. Therefore, the disclosed embodiments are used in a generic and descriptive sense only and not for purposes of limitation.

What is claimed is:

1. A light emitting element comprising:
a semiconductor stack including a first semiconductor layer, an active layer, and a second semiconductor layer that are sequentially disposed in a thickness direction,
wherein a thickness of the first semiconductor layer is 100 nm or less or is less than ⅙ of a thickness of the semiconductor stack.

2. The light emitting element of claim 1, wherein the first semiconductor layer includes an n-type semiconductor, and
the second semiconductor layer includes a p-type semiconductor.

3. The light emitting element of claim 1, wherein a thickness of the semiconductor stack is smaller than or equal to a width of the semiconductor stack.

4. The light emitting element of claim 1, further comprising an electrode layer disposed on a lower surface of the semiconductor stack,
wherein the electrode layer includes a conductive material having a density higher than a density of a semiconductor material included in the semiconductor stack.

5. The light emitting element of claim 4, wherein the semiconductor stack includes gallium nitride (GaN), and
the electrode layer includes at least one of hafnium (Hf), tantalum (Ta), molybdenum (Mo), tungsten (W), rhenium (Re), copper (Cu), silver (Ag), gold (Au), palladium (Pd), and platinum (Pt).

6. The light emitting element of claim 4, wherein a lower surface of the electrode layer has a bend.

7. The light emitting element of claim 4, further comprising a reflective layer disposed between the lower surface of the semiconductor stack and the electrode layer.

8. The light emitting element of claim 1, further comprising an adhesive layer disposed on a lower surface of the semiconductor stack.

9. A light emitting element comprising:
a semiconductor stack including a first semiconductor layer, an active layer, and a second semiconductor layer that are sequentially disposed in a thickness direction; and
an electrode layer disposed on a lower surface of the semiconductor stack,
wherein the electrode layer includes a conductive material having a density higher than a density of a semiconductor material included in the semiconductor stack.

10. The light emitting element of claim 9, wherein the semiconductor stack includes gallium nitride (GaN), and
the electrode layer includes at least one of hafnium (Hf), tantalum (Ta), molybdenum (Mo), tungsten (W), rhenium (Re), copper (Cu), silver (Ag), gold (Au), palladium (Pd), and platinum (Pt).

11. The light emitting element of claim 9, wherein a lower surface of the electrode layer has a bend.

12. The light emitting element of claim 9, further comprising a reflective layer disposed between the lower surface of the semiconductor stack and the electrode layer.

13. An electronic device comprising:
a display module including a display panel; and
a processor configured to transmit an image data signal to the display module,
wherein the display panel comprises a backplane substrate, an electrode disposed on the backplane substrate, and a light emitting element disposed on the electrode,
wherein the light emitting element includes a semiconductor stack including a first semiconductor layer, an active layer, and a second semiconductor layer that are sequentially disposed in a thickness direction, and
wherein a thickness of the first semiconductor layer is 100 nm or less or is less than ⅙ of a thickness of the semiconductor stack.

14. The electronic device of claim 13, wherein the first semiconductor layer includes an n-type semiconductor, and
the second semiconductor layer includes a p-type semiconductor.

15. The electronic device of claim 13, wherein a thickness of the semiconductor stack is smaller than or equal to a width of the semiconductor stack.

16. The electronic device of claim 13, wherein the light emitting element further includes an electrode layer disposed on a lower surface of the semiconductor stack, and
the electrode layer includes a conductive material having a density higher than a density of a semiconductor material included in the semiconductor stack.

17. The electronic device of claim 16, wherein the semiconductor stack includes gallium nitride (GaN), and
the electrode layer includes at least one of hafnium (Hf), tantalum (Ta), molybdenum (Mo), tungsten (W), rhenium (Re), copper (Cu), silver (Ag), gold (Au), palladium (Pd), and platinum (Pt).

18. The electronic device of claim 16, wherein a lower surface of the electrode layer has a bend.

19. The electronic device of claim 16, wherein the light emitting element further includes a reflective layer disposed between the lower surface of the semiconductor stack and the electrode layer.

20. The electronic device of claim 13, wherein the light emitting element further includes an adhesive layer disposed on a lower surface of the semiconductor stack.
